(19) United States
(12) Patent Application Publication
(10) Pub. No.: US 2024/0183946 A1
(43) Pub. Date: Jun. 6, 2024

(54) ILLUMINATION DEVICE AND DISTANCE MEASURING DEVICE

(71) Applicant: SONY SEMICONDUCTOR SOLUTIONS CORPORATION, KANAGAWA (JP)

(72) Inventors: JIALUN XU, KANAGAWA (JP); TAKASHI KOBAYASHI, KANAGAWA (JP); MIDORI KANAYA, KANAGAWA (JP); TATSUYA OIWA, KANAGAWA (JP)

(21) Appl. No.: 18/552,051

(22) PCT Filed: Feb. 15, 2022
(86) PCT No.: PCT/JP2022/005921

§ 371 Date: Sep. 22, 2023

(30) Foreign Application Priority Data
Apr. 14, 2021 (JP) 2021-068625

(51) Int. Cl. G01S 7/481; G01S 17/894

(52) U.S. Cl. CPC G01S 7/4815; G01S 17/894

(57) ABSTRACT

For example, a decrease in beam intensity at a portion where beam profiles overlap in uniform irradiation is suppressed. Provided is an illumination device including a light emitting element including a plurality of light emission units, in which, when an irradiation target object is irradiated with a light beam emitted from the plurality of light emission units, in a case where a portion corresponding to a center of the light beam is set as a light beam center, and predetermined two light beam centers are set as a first light beam center and a second light beam center, and in a case where an angle formed by the first light beam center and the second light beam center with respect to the light emitting element is set as a first angle, and an angle at which a beam intensity of a beam profile corresponding to the first light beam center becomes a predetermined intensity in an extending direction of a line including the first light beam center and the second light beam center is set as a second angle, the first angle is substantially equal to the second angle.

### TECHNICAL FIELD

The present technology relates to an illumination device and a distance measuring device.

### BACKGROUND ART

There have been proposed various distance measuring methods (for example, the time of flight (ToF) method) for measuring a distance to a measuring target object by irradiating the measuring target object with light emitted from a plurality of light emission units and receiving reflected light from the measuring target object. For example, Patent Document 1 describes a vertical cavity surface emitting laser (VCSEL) using GaAs, InP, or the like for a substrate used for distance measurement.

### CITATION LIST

### Patent Document

Patent Document 1: Japanese Patent Application Laid-Open No. 2011-61083

### SUMMARY OF THE INVENTION

### Problems to be Solved by the Invention

In such a field, it is desired to improve the accuracy of distance measurement.

An object of the present technology is to provide a novel and useful illumination device and a distance measuring device that solve such a problem.

### Solutions to Problems

The present technology is an illumination device including:
a light emitting element including a plurality of light emission units,
in which, when an irradiation target object is irradiated with a light beam emitted from the plurality of light emission units, in a case where a portion corresponding to a center of the light beam is set as a light beam center, and predetermined two light beam centers are set as a first light beam center and a second light beam center, and
in a case where an angle formed by the first light beam center and the second light beam center with respect to the light emitting element is set as a first angle, and an angle at which a beam intensity of a beam profile corresponding to the first light beam center becomes a predetermined intensity in an extending direction of a line including the first light beam center and the second light beam center is set as a second angle, the first angle is substantially equal to the second angle.

The present technology is a distance measuring device including:
the illumination device described above;
a control unit that controls the illumination device;
a light receiving unit that receives reflected light reflected from a target object; and
a distance measuring unit that calculates a distance measurement distance from image data obtained by the light receiving unit.

### BRIEF DESCRIPTION OF DRAWINGS

FIG. 1 is a block diagram illustrating an example of a schematic configuration of a distance measuring device including an illumination device according to one embodiment.

FIG. 2A is a diagram illustrating an irradiation pattern at the time of spot irradiation by the illumination device, and FIG. 2B is a diagram illustrating an irradiation pattern at the time of uniform irradiation by the illumination device.

FIG. 3 is a schematic cross-sectional view illustrating an example of a schematic configuration of the illumination device according to one embodiment.

FIG. 4 is a schematic cross-sectional view illustrating an example of a light emitting element according to one embodiment.

FIG. 5 is a schematic cross-sectional view illustrating another example of the light emitting element according to one embodiment.

FIG. 6 is a schematic view illustrating an example of a planar configuration of the light emitting element.

FIG. 7A is a schematic plan view illustrating an example of a configuration of a microlens array according to one embodiment, and FIG. 7B is a schematic view illustrating an example of a cross-sectional configuration of the microlens array of FIG. 7A.

FIG. 8A is a schematic view illustrating a position of a light emission unit for uniform irradiation with respect to the microlens array illustrated in FIG. 7A, and FIG. 8B is a schematic view illustrating a position of a light emission unit for spot irradiation with respect to the microlens array illustrated in FIG. 7A.

FIG. 9 is a diagram for explaining a beam forming function according to one embodiment.

FIG. 10 is a diagram illustrating an irradiation pattern for an irradiation target object according to one embodiment.

FIG. 11 is a diagram for explaining a difference in light emission area between different light emission units.

FIG. 12 is a diagram illustrating an example of a configuration of a drive circuit of the illumination device.

FIG. 13 is a diagram for explaining a light emission sequence of the illumination device.

FIG. 14 is a diagram to be referred to in describing terms used in the present embodiment.

FIG. 15 is a diagram to be referred to in describing a near field pattern and a far field pattern.

FIG. 16 is a diagram for explaining an example of a case where diffraction elements are arranged in FIG. 14.

FIGS. 17A and 17B are diagrams for explaining a division pattern of diffracted light.

FIG. 18 is a diagram illustrating a state in which the light emitting element is brought closer than an actual focus position of the refractive element.

FIG. 19 is a diagram illustrating a state in which the light emitting element is set away from an actual focus position of the refractive element.

FIGS. 20A to 20C are diagrams to be referred to in describing problems to be considered in one embodiment.

FIG. 21 is a diagram to be referred to in describing an outline of one embodiment.

FIGS. 22A and 22B are diagrams to be referred to in describing an outline of one embodiment.

FIG. 23 is a diagram to be referred to in describing an outline of one embodiment.

FIG. 24 is a diagram to be referred to in describing an angle formed by adjacent light beam centers in one embodiment.

FIG. 25 is a diagram to be referred to in describing a relationship between an angle formed by adjacent light beam centers and an angle at which a beam intensity becomes a predetermined intensity.

FIG. 26A illustrates an example of a beam profile (XY beam profile), and FIG. 26B is a diagram schematically illustrating a state in which an irradiation target object is irradiated with a plurality of beam profiles illustrated in FIG. 26A.

FIG. 27 is a diagram illustrating an arrangement example of a plurality of beam profiles.

FIG. 28A illustrates an example of a beam profile (XY beam profile), and FIG. 28B is a diagram schematically illustrating a state in which an irradiation target object is irradiated with a plurality of beam profiles illustrated in FIG. 28A.

FIG. 29 is a diagram illustrating an arrangement example of a plurality of beam profiles.

FIG. 30 is a diagram illustrating an arrangement example of a plurality of beam profiles.

FIGS. 31A and 31B illustrate examples of beam profiles having different shapes, and FIG. 31C is a diagram illustrating an arrangement example of the beam profiles illustrated in FIGS. 31A and 31B.

FIGS. 32A to 32C are diagrams for explaining an example of a beam profile shaping method.

FIGS. 33A to 33C are diagrams for explaining another example of the beam profile shaping method.

FIGS. 34A to 34C are diagrams for explaining another example of the beam profile shaping method.

FIG. 35 is a diagram to be referred to in describing the SR structure.

FIG. 36 is a diagram for explaining another example of the beam profile shaping method.

FIG. 37 is a diagram for explaining another example of the beam profile shaping method.

FIG. 38A to FIG. 38D are diagrams to be referred to in describing a predetermined intensity in one embodiment.

FIG. 39A to FIG. 39C are diagrams to be referred to in describing a predetermined intensity in one embodiment.

FIG. 40A to FIG. 40C are diagrams to be referred to in describing a predetermined intensity in one embodiment.

FIGS. 41A to 41C are diagrams for explaining modifications.

FIGS. 42A to 42C are diagrams for explaining modifications.

FIG. 43 is a diagram for explaining modifications.

FIG. 44 is a diagram for explaining modifications.

### MODE FOR CARRYING OUT THE INVENTION

An embodiment and the like of the present technology are hereinafter described with reference to the drawings. Note that the description will be given in the following order.

### Embodiment

### Modifications

Note that the embodiment and the like hereinafter described are preferred specific examples of the present technology, and the contents of the present technology are not limited to the embodiment and the like.

### Embodiment

### [Configuration of Distance Measuring Device]

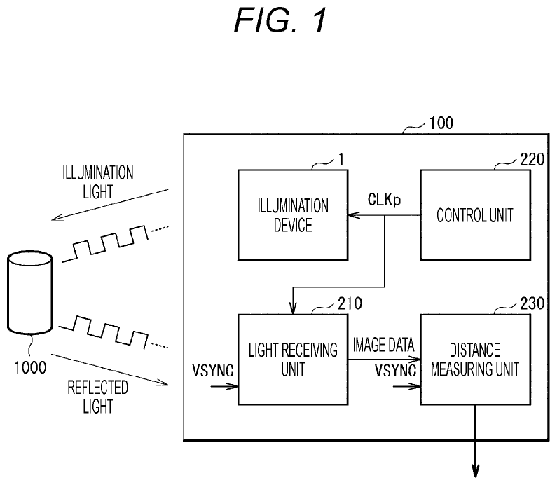

FIG. 1 is a block diagram illustrating an example of an overall configuration of a distance measuring device 100 according to one embodiment of the present technology.

The distance measuring device 100 is a device that measures a distance to an irradiation target object 1000 by irradiating the irradiation target object 1000 with illumination light and receiving the reflected light. The distance measuring device 100 includes an illumination device 1, a light receiving unit 210, a control unit 220, and a distance measuring unit 230.

The illumination device 1 generates irradiation light in synchronization with a rectangular wave light emission control signal CLKp from the control unit 220. The light emission control signal CLKp is only required to be a periodic signal, and the light emission control signal CLKp is not limited to the rectangular wave. For example, the light emission control signal CLKp may be a sine wave.

The light receiving unit 210 receives the light reflected from the irradiation target object 1000 and detects, each time a period of a vertical synchronization signal VSYNC elapses, an amount of the received light within the period. In the light receiving unit 210, a plurality of pixel circuits is disposed in a two-dimensional lattice pattern. The light receiving unit 210 supplies image data (frame) corresponding to the amount of the light received by these pixel circuits to the distance measuring unit 230. Note that the light receiving unit 210 has, for example, a function of correcting a distance measurement error due to multipath.

The control unit 220 controls the illumination device 1 and the light receiving unit 210. The control unit 220 generates the light emission control signal CLKp and supplies the light emission control signal CLKp to the illumination device 1 and the light receiving unit 210.

The distance measuring unit 230 measures a distance to the irradiation target object 1000 by a ToF method on the basis of the image data. The distance measuring unit 230 measures the distance for each pixel circuit and generates a depth map indicating a distance to an object as a gradation level value for each pixel. This depth map is used for, for example, image processing of performing blurring processing with a degree corresponding to a distance, autofocus (AF) processing of obtaining a focal point of a focus lens according to a distance, and the like.

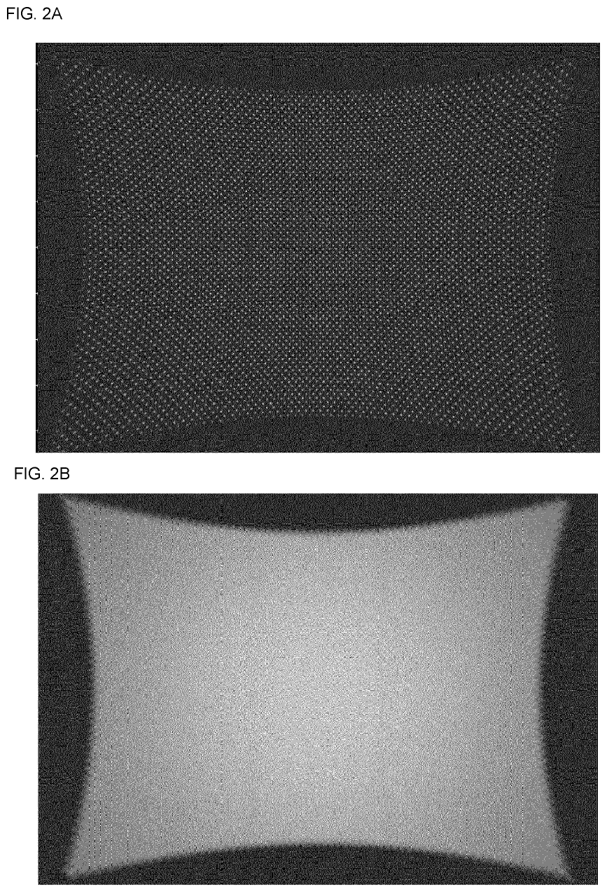

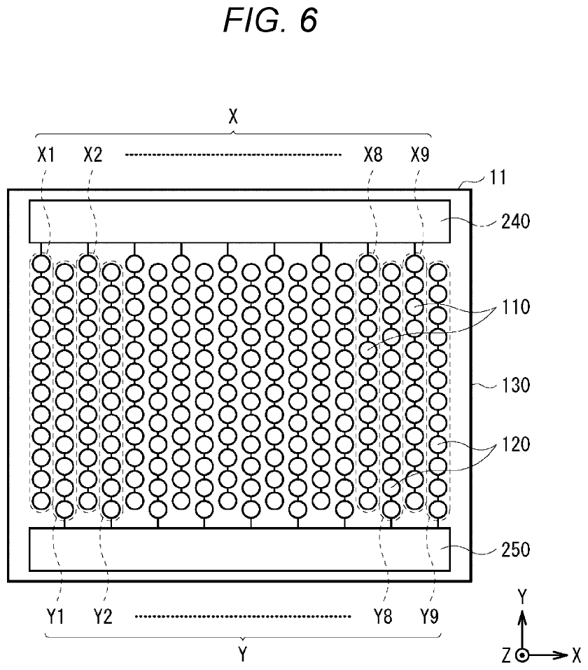

The illumination device 1 according to one embodiment emits light from a plurality of light emission units (light emission units 110 (first light emission unit) and 120 (second light emission unit), see FIG. 6). A diffraction element 14 to be described later is an optical element that tiles the light L1 and widens the irradiation range to the light L2, and it is possible to widen the irradiation range by tiling to 3×3. The light L110 and L120 perform, for example, spot irradiation as illustrated in FIG. 2A, uniform irradiation as illustrated in FIG. 2B, and simultaneous irradiation thereof.

### [Configuration of Illumination Device]

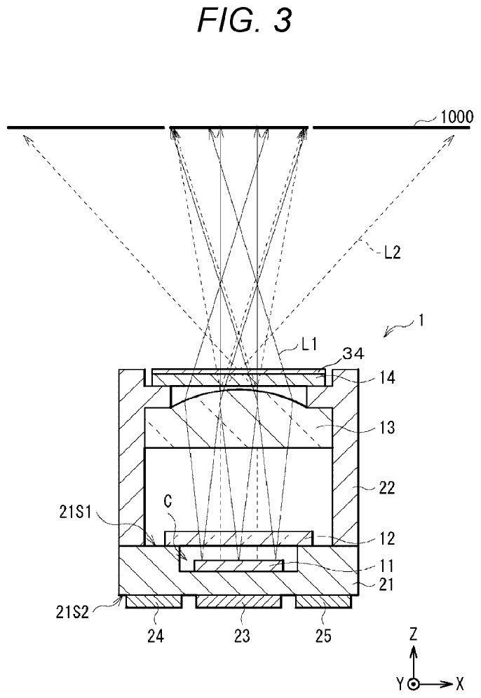

As illustrated in FIG. 3, the illumination device 1 includes, for example, a light emitting element 11, a microlens 12, a collimator lens 13, a diffraction element 14, and a diffraction element 34. The microlens 12, the collimator lens 13, the diffraction element 14, and the diffraction element 34 are arranged, for example, in this order on an optical path of light (light L110 and L120) emitted from the light emitting element 11. The light emitting element 11 is held by, for example, a holding unit 21, and the collimator lens 13 and the diffraction element 14 are held by, for example, a holding unit 22. The diffraction element 34 is supported by the diffraction element 14 by adhesion or the like. The holding unit 21 includes, for example, one cathode electrode unit 23 and two anode electrode units 24 and 25 on a surface 212 opposite to a surface 21S1 holding the light emitting element 11. Hereinafter, each member constituting the illumination device 1 will be described in detail.

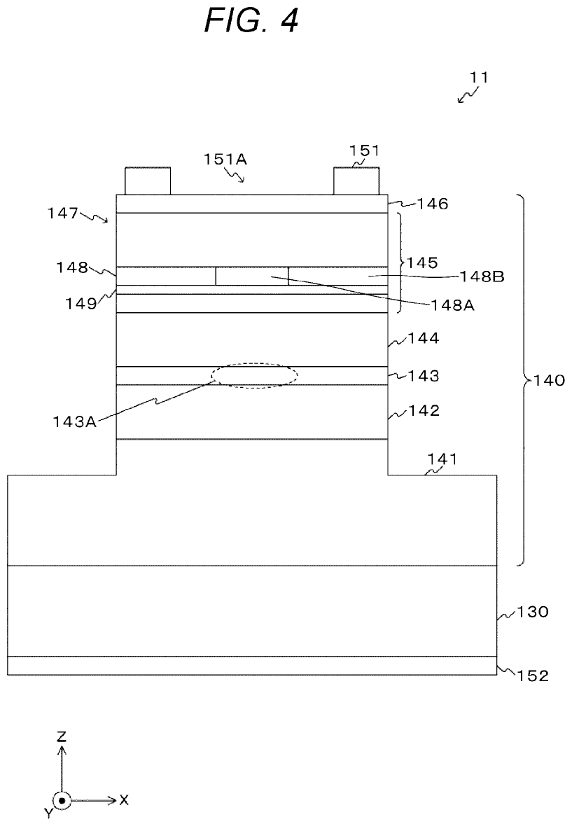

The light emitting element 11 is, for example, a surface emitting type surface emitting semiconductor laser. FIG. 4 is a cross-sectional view illustrating a first structural example of the light emitting element 11 according to one embodiment of the present technology.

The light emitting elements 11 are arranged in an array on the substrate 130. The light emitting element 11 includes a semiconductor layer 140 including a lower distributed Bragg reflector (DBR) layer 141, a lower spacer layer 142, an active layer 143, an upper spacer layer 144, an upper DBR layer 145, and a contact layer 146 in this order on a front surface side of the substrate 130. An upper portion of the semiconductor layer 140, specifically, a part of the lower DBR layer 141, the lower spacer layer 142, the active layer 143, the upper spacer layer 144, the upper DBR layer 145, and the contact layer 146 form a columnar mesa portion 147. In the mesa portion 147, the center of the active layer 143 forms a light emitting region 143A. Furthermore, the upper DBR layer 145 is provided with a current confinement layer 148 and a buffer layer 149.

The substrate 130 is, for example, an n-type GaAs substrate. Examples of an n-type impurity include, for example, silicon (Si), selenium (Se), and the like. The semiconductor layers are each constituted by, for example, an AlGaAs-based compound semiconductor. The AlGaAs-based compound semiconductor refers to a compound semiconductor containing at least aluminum (Al) and gallium (Ga) among Group 13 elements in the periodic table of elements and at least arsenic (As) among Group 15 elements in the periodic table of elements.

The lower DBR layer 141 is formed by alternately laminating a low refractive index layer and a high refractive index layer (both not illustrated). The low refractive index layer is constituted by, for example, n-type Alₓ₁Ga₁₋ₓ₁As (0<x1<1) having a thickness of λ₀/4n₁ (λ₀ represents an emission wavelength, and n₁ represents a refractive index). The high refractive index layer is constituted by, for example, n-type Alₓ₂Ga₁₋ₓ₂As (0<x2<x1) having a thickness of λ₀/4n₂ (n2 is a refractive index).

The lower spacer layer 142 is constituted by, for example, n-type Alₓ₃Ga₁₋ₓ₃As (0<x3<1). The upper spacer layer 144 is constituted by, for example, p-type Alₓ₅Ga₁₋ₓ₅As (0<x5<1). Examples of a p-type impurity include, for example, zinc (Zn), magnesium (Mg), beryllium (Be), and the like.

The active layer 143 has a multi quantum well structure (MQW). The active layer 143 is constituted by, for example, undoped n-type Alₓ₋₄Ga₁₋ₓ₄As (0<x4<1).

The upper DBR layer 145 is formed by alternately laminating a low refractive index layer and a high refractive index layer (both not illustrated). The low refractive index layer is constituted by, for example, p-type Alₓ₈Ga₁₋ₓ₈As (0<x8<1) having a thickness of λ₀/4n₃ (n₃ is a refractive index). The high refractive index layer is constituted by, for example, p-type Alₓ₉Ga₁₋ₓ₉As (0<x9<x8) having a thickness of λ₀/4n₄ (n₄ is a refractive index). The contact layer 146 is constituted by, for example, p-type Alₓ₁₀Ga₁₋ₓ₁₀As (0<x10<1).

The current confinement layer 148 and the buffer layer 149 are provided, for example, in the lower DBR layer 141. The current confinement layer 148 is formed at a position away from the active layer 143 in relation to the buffer layer 149. The current confinement layer 148 is provided, for example, in place of the low refractive index layer in a portion of the low refractive index layer that is, for example, several layers away from the active layer 143 side in the lower DBR layer 141. The current confinement layer 148 has a current injection region 148A and a current confinement region 148B. The current injection region 148A is formed in a central region in the plane. The current confinement region 148B is formed in a peripheral edge of the current injection region 148A, that is, an outer edge region of the current confinement layer 148, and has an annular shape.

The current injection region 148A is constituted by, for example, n-type Alₓ₁₁Ga₁₋ₓ₁₁As (0.98≤x11≤1). The current confinement region 148B is constituted by, for example, aluminum oxide (Al₂O₃), and is obtained by oxidizing an oxidized layer (not illustrated) constituted by, for example, n-type Alₓ₁₁Ga₁₋ₓ₁₁As from the side surface of the mesa portion 147. As a result, the current confinement layer 148 has a function of constricting the current.

The buffer layer 149 is formed closer to the active layer 143 in relation to the current confinement layer 148. The buffer layer 149 is formed adjacent to the current confinement layer 148. For example, as illustrated in FIG. 4, the buffer layer 149 is formed in contact with a surface (lower surface) of the current confinement layer 148 on the active layer 143 side. Note that a thin layer having a thickness of, for example, about several nm may be provided between the current confinement layer 148 and the buffer layer 149. The buffer layer 149 is provided, for example, in place of the high refractive index layer in a portion of the high refractive index layer that is, for example, several layers away from the current confinement layer 148 in the lower DBR layer 141.

The buffer layer 149 has an unoxidized region and an oxidized region (both not illustrated). The unoxidized region is mainly formed in a central region in the plane, and is formed, for example, at a portion in contact with the current injection region 148A. The oxidized region is formed on a peripheral edge of the unoxidized region and has an annular shape. The oxidized region is mainly formed in the outer edge region in the plane, and is formed, for example, in a portion in contact with the current confinement region 148B. The oxidized region is formed to be biased toward the current confinement layer 148 side in a portion other than the portion corresponding to the outer edge of the buffer layer 149.

The unoxidized region is constituted by a semiconductor material containing Al, and is constituted by, for example, n-type Alₓ₁₂Ga₁₋ₓ₁₂As (0.85<x12≤0.98) or n-type InₐAlₓ₁₃Ga₁₋ₓ₁₃₋ₐAs (0.85<x13≤0.98). The oxidized region includes, for example, aluminum oxide (Al₂O₃), and is obtained by oxidizing a layer to be oxidized (not illustrated) including, for example, n-type Alₓ₁₂Ga₁₋ₓ₁₂As or n-type In_{b}Alₓ₁₃Ga_{1-x13-b}As from the side surface side and the layer to be oxidized side of the mesa portion 147. The layer to be oxidized of the buffer layer 149 is constituted by a material and a thickness that have a higher oxidation rate than the upper DBR layer 145 and the lower DBR layer 141 and a lower oxidation rate than the layer to be oxidized of the current confinement layer 148.

On the upper surface of the mesa portion 147 (the upper surface of the contact layer 146), an annular upper electrode 151 having an opening (light emission port 151A) in a region facing at least the current injection region 148A is formed. In addition, an insulating layer (not illustrated) is formed on a side surface and a peripheral surface of the mesa portion 147. The upper electrode 151 is connected to different electrode pads by wire bonding or the like by wiring (not illustrated) for each light emission unit group. In addition, a lower electrode 152 is provided on the other surface of the substrate 130. The lower electrode 152 is electrically connected to, for example, the cathode electrode unit 23. As described above, one embodiment is an embodiment in which the cathode electrode unit is a common electrode, and the anode electrode unit is separately provided.

Here, the upper electrode 151 is formed by, for example, laminating titanium (Ti), platinum (Pt), and gold (Au) in this order, and is electrically connected to the contact layer 146 above the mesa portion 147. The lower electrode 152 has a structure in which, for example, an alloy of gold (Au) and germanium (Ge), nickel (Ni), and gold (Au) are laminated in order from the substrate 130 side, and is electrically connected to the substrate 130.

The plurality of light emission units has a configuration in which, for example, a plurality of light emission units (a plurality of light emission units 110 for spot irradiation) used for spot irradiation and a plurality of light emission units (a plurality of light emission units 120 for uniform irradiation) used for uniform irradiation are arranged in an array on the substrate 130. The plurality of light emission units 110 and the plurality of light emission units 120 are physically and electrically separated from each other by the mesa structure of the mesa portion 147.

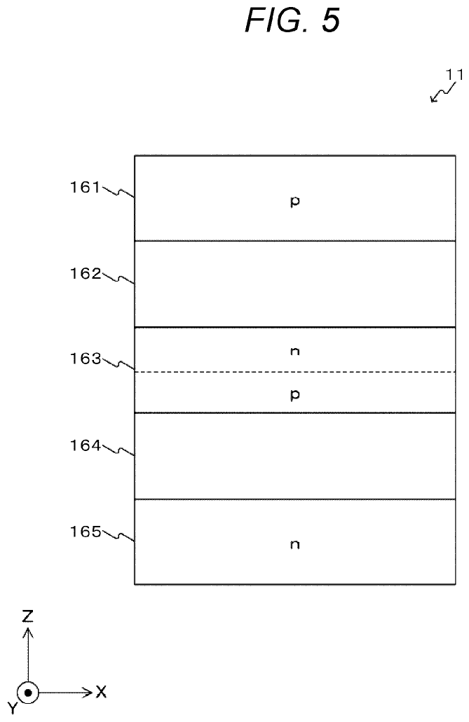

FIG. 5 is a cross-sectional view illustrating a second structural example of the light emitting element 11 according to one embodiment of the present technology.

The light emitting element 11 of the second configuration example is a multi-junction VCSEL, and has a structure in which a P-DBR layer 161, an active layer 162, a tunnel junction 163, an active layer 164, and an N-DBR layer 165 are stacked in order from the radiation side. That is, two pn junctions are connected, and active layers (active regions) 162 and 164 that emit a laser oscillation wavelength are stacked between the pn junctions in a vertical direction. By providing a plurality of the active layers 162 and 164 in this manner, the output of the light of each of the light emitting elements 11 may be improved (refer to “Zhu Wenjun, et. al: ‘Analysis of the operating point of a novel multiple-active region tunneling-regenerated vertical-cavity surface-emitting laser’, Proc. of International Conference on Solid-State and Integrated Circuit Technology, Vol. 6, pp. 1306-1309, 2001”). According to this multi-junction VCSEL, it is possible to reduce a size and a cost of the element. Note that although omitted in the second structural example, similarly to the first structural example, a spacer layer in the vicinity of the active layer, a buffer layer, a current confinement layer, a mesa portion, a light emission port, an upper electrode layer, and a lower electrode layer may be provided.

In one embodiment of the present technology, since spot light is divided by the diffraction element 34, it is possible to increase the number of spots while maintaining or enhancing light intensity of the spot light by combining with the multi-junction VCSEL. Then, therefore, both distance measurement accuracy and distance measurement resolution may be satisfied.

The above-described light emitting element 11 includes, for example, a plurality of light emission units 110 and a plurality of light emission units 120. The plurality of light emission units 110 and the plurality of light emission units 120 are electrically connected to each other. Specifically, for example, as illustrated in FIG. 6, the plurality of light emission units 110 constitutes a plurality of (for example, nine in FIG. 6) light emission unit groups X (light emission unit groups X1 to X9) including n (for example, 12 in FIG. 6) light emission units 110 extending in one direction (for example, in the Y-axis direction). Similarly, the plurality of light emission units 120 constitutes a plurality of (for example, nine in FIG. 6) light emission unit groups Y (light emission unit groups Y1 to Y9) including m (for example, 12 in FIG. 6) light emission units 120 extending in one direction (for example, in the Y-axis direction). As illustrated in FIG. 6, the light emission unit groups X1 to X9 and the light emission unit groups Y1 to Y9 are alternately arranged on the substrate 130 having a rectangular shape, for example. The light emission unit groups X1 to X9 are electrically connected to, for example, an electrode pad 240 provided along one side of the substrate 130, and the light emission unit groups Y1 to Y9 are electrically connected to, for example, an electrode pad 250 provided along another side facing the one side of the substrate 130. Note that, although FIG. 6 illustrates an example in which the light emission unit groups X1 to X9 and Y1 to Y9 are alternately arranged, the present invention is not limited thereto. For example, the number of the plurality of light emission units 110 and the number of the plurality of light emission units 120 can be arbitrarily arranged depending on the number and position of desired light emission points and the amount of light output. As an example, the plurality of light emission units 120 may be arranged in every two rows of the plurality of light emission units 110.

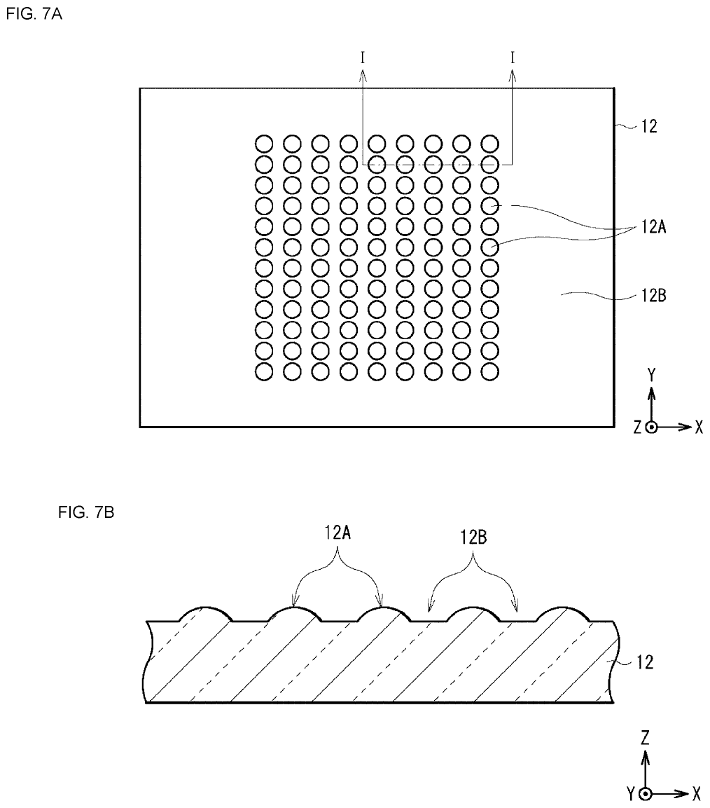

For example, the microlens 12 forms a shape of at least one beam of light (hereinafter, these will be appropriately referred to as a laser beam L110 and a laser beam L120) emitted from the plurality of the light emission units 110 for spot irradiation or the plurality of the light emission units 120 for uniform irradiation and emits the beam. FIG. 7A schematically illustrates an example of a planar configuration of the microlens 12, and FIG. 7B schematically illustrates a cross-sectional configuration of the microlens 12 taken along line I-I illustrated in FIG. 7A. In the microlens 12, a plurality of microlenses is disposed in an array, and the microlens 12 includes a plurality of lens portions 12A and a parallel plate portion 12B.

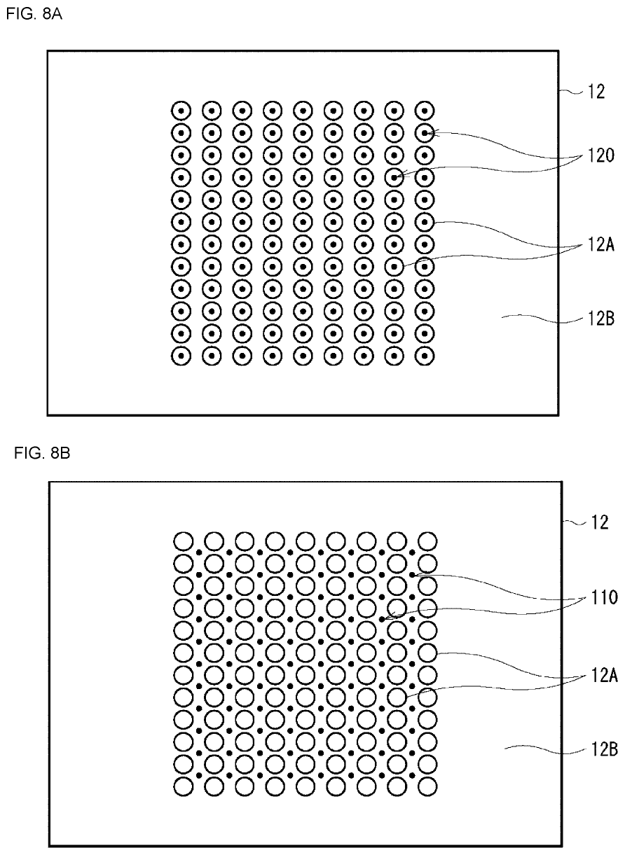

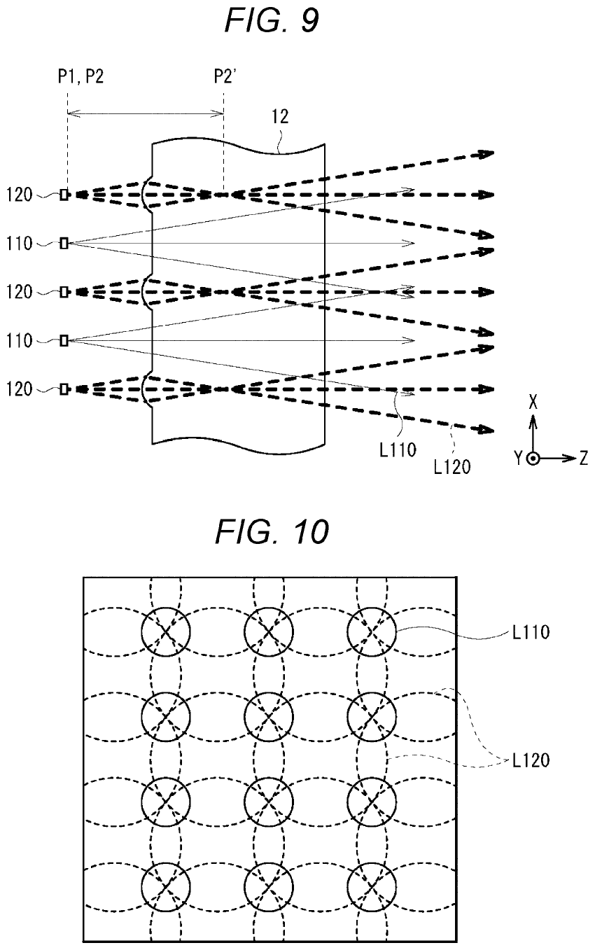

In one embodiment, as illustrated in FIG. 8A, the microlens 12 is disposed such that the lens portions 12A respectively face the plurality of light emission units 120 for uniform irradiation, and as illustrated in FIG. 8B, the parallel plate portion 12B faces the plurality of light emission units 110 for spot irradiation. As a result, as illustrated in FIG. 9, the laser beams L120 emitted from the plurality of light emission units 120 are refracted by the lens surface of the lens portion 12A, and form, for example, a light beam center P2′ in the microlens 12. That is, a light emission point P2 of each of the plurality of light emission units 120 at the same height as a light emission point P1 of each of the plurality of light emission units 110 is shifted in an optical axis direction (for example, in the Z-axis direction) of the light beams (the laser beams L110 and the laser beams L120) emitted from the plurality of light emission units 110 and the plurality of light emission units 120.

Therefore, by switching the light emission of the plurality of light emission units 110 and the plurality of light emission units 120, the laser beams L110 emitted from the plurality of light emission units 110 pass through the microlens 122 as they are (without being refracted), and form a spot-shaped irradiation pattern as illustrated in FIG. 10, for example. Further, the laser beams L120 emitted from the plurality of light emission units 120 are refracted by the microlens 122, and for example, as illustrated in FIG. 10, partially overlap the laser beams L120 emitted from the adjacent light emission units 120, thereby forming an irradiation pattern for irradiating a predetermined range with substantially uniform light intensity. In the illumination device 1, by switching between the light emission of the plurality of light emission units 110 and the light emission of the plurality of light emission units 120, it is possible to switch between spot irradiation and uniform irradiation.

Note that FIG. 9 illustrates an example in which the microlens 12 functions as a relay lens, but the present technology is not limited thereto. For example, the light beam center P2′ of the plurality of light emission units 120 may be formed between the light emission unit 120 and the microlens 12.

Note that, as schematically illustrated in FIG. 11, the plurality of light emission units 110 and the plurality of light emission units 120 preferably have different light emission areas (OA diameters W3 and W4). Specifically, the light emission area (OA diameter W3) of the plurality of light emission units 110 for spot irradiation is preferably smaller than the light emission area (OA diameter W4) of the plurality of light emission units 120 for uniform irradiation. As a result, the light beams for spot irradiation (the laser beam L110 (first light) emitted to the irradiation target object 1000 in a spot shape independent from each other) emitted from the plurality of light emission units 110 are condensed smaller, and the target object can be irradiated with a smaller spot. In addition, a wider range can be irradiated with the light beams for uniform irradiation (the laser beam L120 (second light) is overlapped on the light emitted from the adjacent light emission units 120, so that the predetermined range is irradiated with the laser beam L120 in a substantially uniform manner with respect to the irradiation target object 1000) emitted from the plurality of light emission units 120, and the irradiation target object 1000 can be uniformly irradiated with light beams with higher output and more uniform. In addition, accordingly, opening width W1 of the wiring connecting each of the plurality of light emission units 110 becomes smaller than opening width W2 of the wiring connecting each of the plurality of light emission units 120. Note that, in FIG. 11, the number of light emission units for spot irradiation and the number of light emission units for uniform irradiation are the same, but may be different. Further, the light emission unit for spot irradiation and the light emission unit for uniform irradiation may have different far field patterns (FFPs).

The collimator lens 13 emits the laser beams L110 emitted from the plurality of light emission units 110 and the laser beams L120 emitted from the plurality of light emission units 120 as substantially parallel light. The collimator lens 13 is, for example, a lens for collimating the laser beam L110 and the laser beam L120 emitted from the light emission units 110 and 120 and coupling them with the diffraction elements 14 and 34.

The diffraction element 14 divides and emits each of the laser beams L110 emitted from the plurality of light emission units 110 and the laser beams L120 emitted from the plurality of light emission units 120. For example, the diffraction element 14 divides the laser beams L110 emitted from the plurality of light emission units 110 and the laser beams L120 emitted from the plurality of light emission units 120 into 3×3. By disposing the diffraction element 14, it is possible to tile the light fluxes of the laser beam L110 and the laser beam L120, for example, to increase the irradiation range. Furthermore, by arranging the diffraction element 34, each spot of the laser beams L110 and L120 to be spot-emitted can be divided into, for example, five, and the number of spots at the time of spot irradiation can be increased.

The holding unit 21 and the holding unit 22 are for holding the light emitting element 11, the collimator lens 13, and the diffraction element 14. Specifically, the holding unit 21 holds the light emitting element 11 in a recess C (see FIG. 3) provided on the upper surface (surface 21S1). The holding unit 22 holds the collimator lens 13 and the diffraction element 14. The holding unit 21 and the holding unit 22 are connected to each other such that the light L1 and the light L2 emitted from the light emitting element 11 are incident on the collimator lens 13, and the light L1 and the light L2 transmitted through the collimator lens 13 become substantially parallel light.

A plurality of electrode units is provided on the back surface (surface 21S2) of the holding unit 21. Specifically, the cathode electrode unit 23 common to the plurality of light emission units 110 for spot irradiation and the plurality of light emission units 120 for uniform irradiation, the anode electrode unit 24 of the plurality of light emission units 110 for spot irradiation, and the anode electrode unit 25 of the plurality of light emission units 120 for uniform irradiation are provided on the surface 212 of the holding unit 21.

Note that the configuration of the plurality of electrode units provided on the surface 21S2 of the holding unit 21 is not limited to the above, and for example, the cathode electrode units of the plurality of light emission units 110 for spot irradiation and the plurality of light emission units 120 for uniform irradiation may be separately formed, or the anode electrode units of the plurality of light emission units 110 for spot irradiation and the plurality of light emission units 120 for uniform irradiation may be formed as the common electrode unit. Further, the collimator lens 13 and the diffraction element 14 may be held by the holding unit 21.

### [Drive Circuit of Illumination Device]

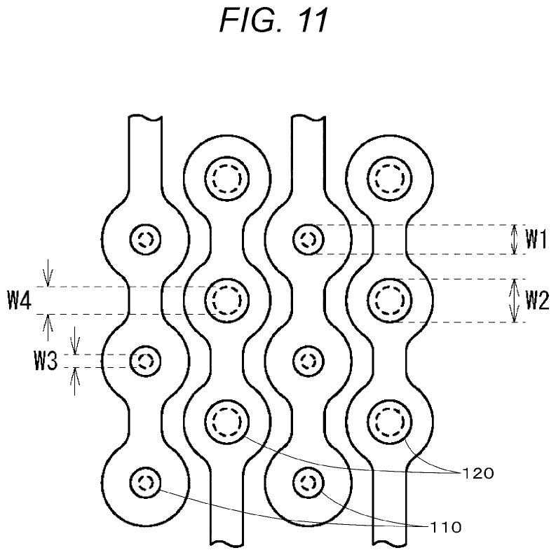

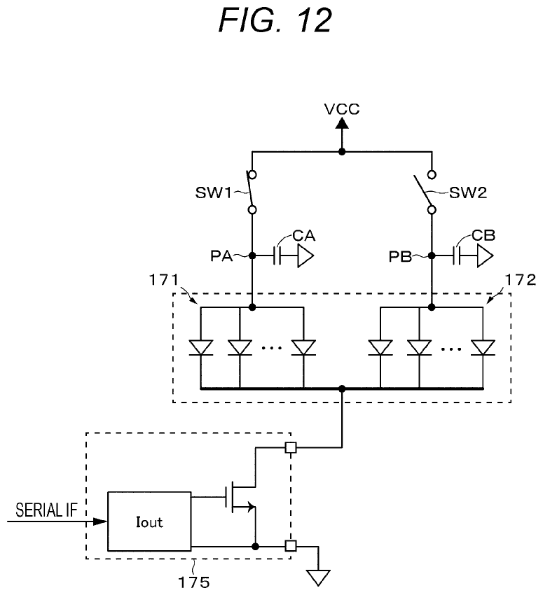

Next, a drive circuit of the illumination device 1 will be described. FIG. 12 illustrates an example of a circuit configuration of a drive circuit that drives the illumination device 1. As illustrated in the drawing, anodes of a first light emission unit group 171 and a second light emission unit group 172 are connected to a power supply (VCC) such as a constant voltage source. Here, the first light emission unit group 171 is, for example, a set of light emission units 110 connected to the electrode pad 240. In addition, the second light emission unit group 172 is, for example, a set of light emission units 120 connected to the electrode pad 250.

The common cathode of the first light emission unit group 171 and the second light emission unit group 172 is connected to a laser driver 175. As the laser driver 175, an N-type metal oxide semiconductor field effect transistor (MOSFET) can be used. As the laser driver 175, a P-type MOSFET or a bipolar transistor may be used.

The first light emission unit group 171 and the second light emission unit group 172 are selectively caused to emit light by the laser driver 175. Which of the first light emission unit group 171 and the second light emission unit group 172 is caused to emit light is performed by opening and closing a first switching unit SW1 and a second switching unit SW2. That is, the light emission of the light emission unit group (first light emission unit group 171) connected to the X side and the light emission of the light emission unit group (second light emission unit group 172) connected to the Y side can be switched by complementary drive control in which one of the two switching units is turned on and the other is turned off. In other words, the first light emission unit group 171 (one channel) and the second light emission unit group 172 (the other channel) can be individually driven.

The first switching unit SW1 is connected between the power supply and the anode of the first light emission unit group 171. The second switching unit SW2 is connected between the power supply and the anode of the second light emission unit group 172. Here, a decoupling capacitor CA is connected to a position close to the first light emission unit group 171, specifically, a connection point PA between the first light emission unit group 171 and the first switching unit SW1. The other end of the decoupling capacitor CA is connected to the ground. Further, a decoupling capacitor CB is connected to a position close to the second light emission unit group 172, specifically, a connection point PB between the second light emission unit group 172 and the second switching unit SW2. The other end of the decoupling capacitor CB is connected to the ground. With this configuration, the charge accumulated in the decoupling capacitor CA can be supplied to the light emission unit 110 constituting the first light emission unit group 171 in a short time, and the charge accumulated in the decoupling capacitor CB can be supplied to the light emission unit 120 constituting the second light emission unit group 172 in a short time. That is, in the illumination device 1, the responsiveness is high, and modulation with a large current can be realized.

Note that one end of the decoupling capacitor CA may be connected between the power supply and the first switching unit SW1, and one end of the decoupling capacitor CB may be connected between the power supply and the second switching unit SW2.

### [Method for Driving Illumination Device]

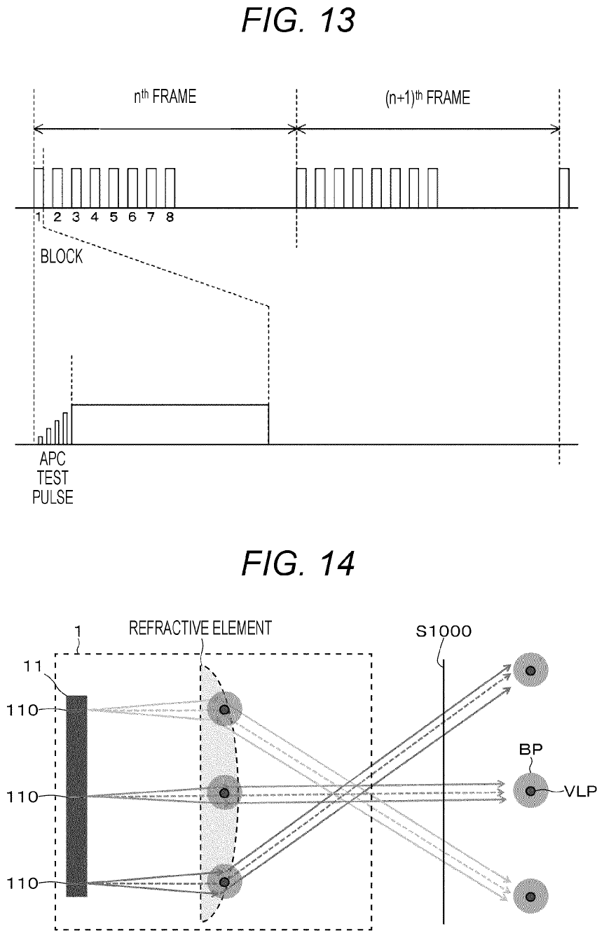

Next, an example of a method of driving the illumination device 1 will be described. FIG. 13 illustrates an example of a light emission sequence of the illumination device 1. A section in which one distance measurement image is generated is referred to as a “frame”, and one frame is set to, for example, a time of 33.3 msec (frequency of 30 Hz). As a distance measurement pulse, for example, a rectangular continuous wave of 100 MHz/Duty=50% is used, and this causes continuous light emission between accumulation sections. A plurality of the accumulation sections with different conditions can be provided in the frame. Although eight accumulation sections are illustrated in FIG. 13, the number of accumulation sections is not limited to this number.

As illustrated in the drawing, in the illumination device 1, the first light emission unit group 171 is caused to emit light in one frame, and the light receiving unit 210 (see FIG. 1) receives the reflected light and generates a distance measurement image. In the next frame, the second light emission unit group 172 is caused to emit light, and the light receiving unit 210 receives reflected light to generate a distance measurement image. Note that, in FIG. 13, the first light emission unit group 171 and the second light emission unit group 172 are switched in each frame, but may be switched in each plurality of frames. Note that light emission of the first light emission unit group 171 and the second light emission unit group 172 may be switched, for example, in units of one frame, in units of blocks, or in units of a plurality of blocks. Therefore, for example, it is possible to switch between two sets of spot irradiation at a faster speed as compared with a method of mechanically switching focal positions of laser beams emitted from a plurality of the light emission units.

### [Relationship Between Position of Light Emission Unit and Beam Profile]

Next, a relationship between the position of the light emission unit and the beam profile will be described.

### Explanation of Terms

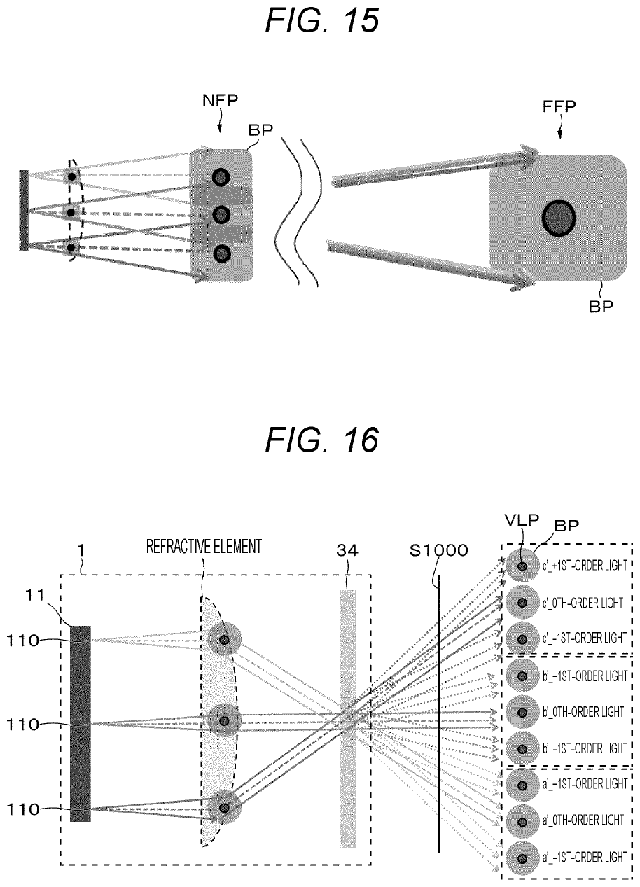

First, terms used in the following description will be described with reference to FIG. 14. Note that, in FIG. 14, the illustration of the configuration of the illumination device 1 is simplified as appropriate. The laser beams emitted from the light emission unit 110 and the light emission unit 120 of the illumination device 1 are emitted to the irradiation target object 1000 (for example, screen S1000) via the refractive element including the collimator lens 13. The arrangement of the light emission units 110 and 120 in the light emitting element 11 is confirmed by using a microscope or the like. In addition, as schematically illustrated in FIG. 15, the beam profile BP of the laser beam is obtained by measuring a beam profile (near field pattern (NFP)) in the vicinity of the emission end and a beam profile (FFP) at a place sufficiently away from the emission end. As a beam profiler method for measuring a beam profile, a known method such as a fixed beam profiler or a scanning beam profiler can be applied.

As schematically illustrated in FIG. 14, for example, the beam profile BP of the laser beam emitted from each of the three light emission units of the light emitting element 11 is usually circular. Hereinafter, the center of the beam profile is appropriately referred to as a light beam center VLP. In addition, the pattern of each beam profile projected on the screen S1000 is appropriately referred to as an array.

The example illustrated in FIG. 14 is an example in which the light emitting element 11 is placed at the actual focus position of the refractive element, but other examples are also conceivable. For example, as illustrated in FIG. 16, the illumination pattern can be projected on the screen S1000 by the laser beam divided by the diffraction element 34. Also in this case, the center of each beam profile is appropriately referred to as a light beam center, and the illumination pattern formed on the screen S1000 is appropriately referred to as an array. Note that FIG. 17A is an example in which the 0th-order light is divided into the +1st-order light and the −1st-order light. As illustrated in FIG. 17B, the 0th-order light may be divided into four. Note that, in FIGS. 17A and 17B, black circles indicate 0th-order light, and white circles indicate divided diffracted light.

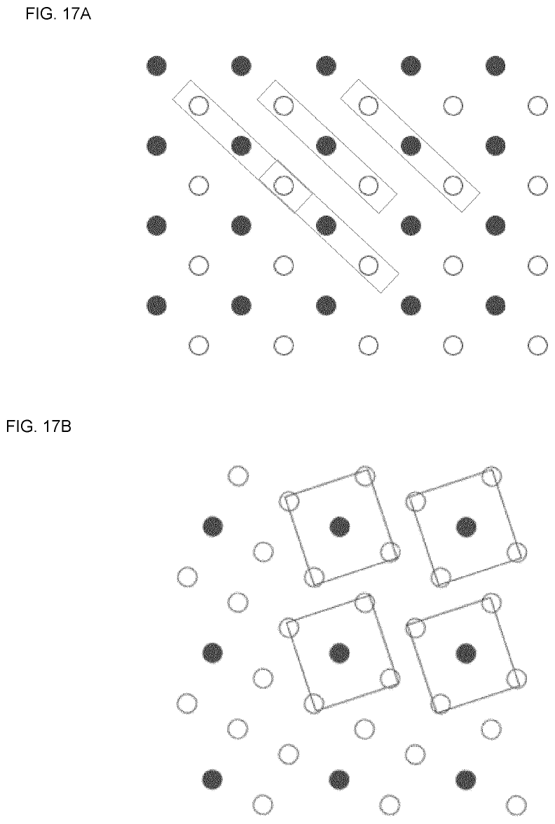

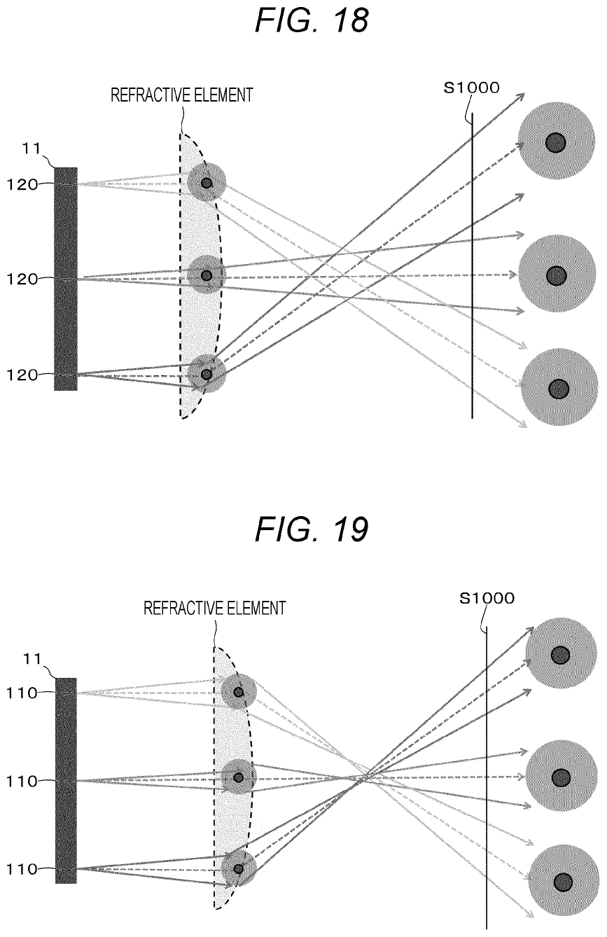

Furthermore, as illustrated in FIG. 18, the light emitting element 11 may be placed closer than the actual focus position of the refractive element. In this case, light is diffused. In addition, there is a case where the light is diverged or converged by shifting the position of the center of the light beam by an optical member such as a microlens as illustrated in FIG. 9 without changing the positional relationship between the light emitting element and the refractive element. Furthermore, as illustrated in FIG. 19, the light emitting element 11 may be placed away from the actual focus position of the refractive element. In this case, the light is once converged and then diffused. In either case, the center of the beam profile is referred to as a light beam center, and the illumination pattern formed on the screen S1000 is referred to as an array.

### Problems to be Considered in Present Technology

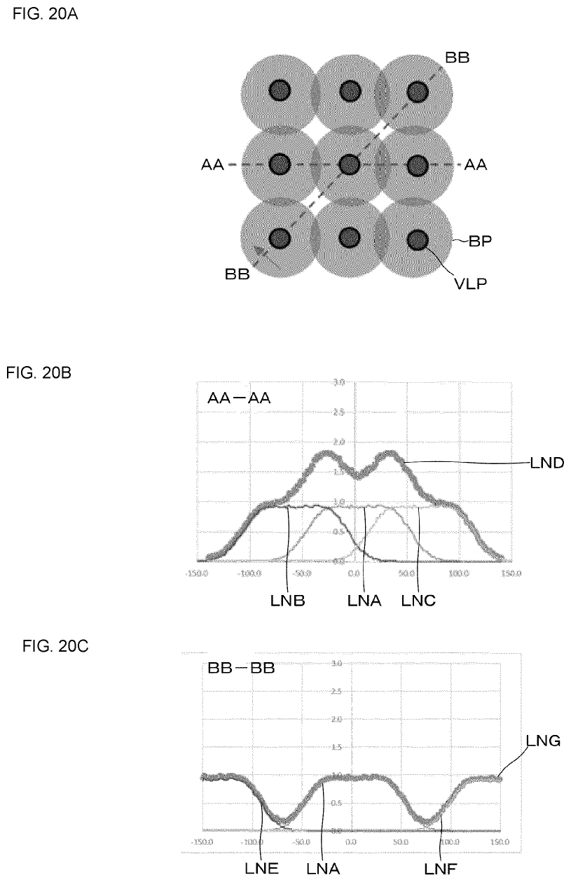

Next, in order to facilitate understanding of the present technology, problems to be considered in the present technology will be described. FIG. 20A is a diagram schematically illustrating a beam profile BP defocused by the microlens 12 and illuminated on the screen S1000. In FIG. 20A, an array (3×3) of nine beam profiles BP is illustrated as an example. Each beam profile BP has a light beam center VLP at its center. The light beam center VLP can also be referred to as a beam profile of the laser beam before being defocused. The arrangement of the light beam centers VLP substantially coincides with the arrangement of the light emission units (in this example, the light emission unit 120) for uniform irradiation. The beam profile BP usually has a shape (usually circular) of a beam profile (near field pattern (NFP)) in the vicinity of the emission end of the light emission unit.

In a case where the arrangement of the light beam centers VLP, in other words, the arrangement of the light emission units 120 is, for example, a lattice arrangement at equal intervals, whereas the shape of the beam profile is circular, the degree of overlapping of the beam profiles BP becomes non-uniform.

For example, as illustrated in FIG. 20A, a line connecting the light beam center VLP of the central beam profile BP and the light beam centers VLP of two beam profiles BP adjacent to the beam profile BP in the horizontal direction is defined as an AA-AA line. Further, a line connecting the light beam center VLP of the central beam profile BP and the light beam centers VLP of two beam profiles BP adjacent to the beam profile BP in the diagonal direction is defined as a BB-BB line.

FIG. 20B illustrates an overlapping state of the three beam profiles BP in the direction of the line AA-AA. In FIG. 20B, the horizontal axis represents the position (unit is arbitrary unit) of each beam profile, and the vertical axis represents normalized beam intensity. The beam profile in this example has a shape called a top-hat shape in which the top is flat.

In FIG. 20B, the line LNA indicates the laser intensity of the central beam profile BP, the line LNB indicates the laser intensity of the left beam profile BP with respect to the central beam profile BP, and the line LNC indicates the laser intensity of the right beam profile BP with respect to the central beam profile BP. The line LND indicates the laser intensity in which the lines LNA to LNC are overlapped. As indicated by the line LND, the laser intensity does not drop in the direction of the AA-AA line.

On the other hand, in FIG. 20C, a line LNA indicates the laser intensity of the central beam profile BP, a line LNE indicates the laser intensity of the lower left beam profile BP with respect to the central beam profile BP, and a line LNF indicates the laser intensity of the lower right beam profile BP with respect to the central beam profile BP. The line LNG indicates the laser intensity in which the lines LNA, LNE, and LNF are overlapped. As indicated by the line LNF, there is an extreme dip in which the laser intensity becomes zero in the direction of the BB-BB line. That is, there is a portion where the irradiation target object 1000 is not irradiated with the uniformly irradiated laser beam, which may deteriorate the accuracy of distance measurement. Even in a case where the laser intensity does not become 0, a similar problem occurs to when the laser intensity at the overlapping portion is less than a predetermined value (for example, less than 25% of the peak intensity of the laser intensity). An object of the present technology is to improve such a point.

### Outline and Details of Present Embodiment

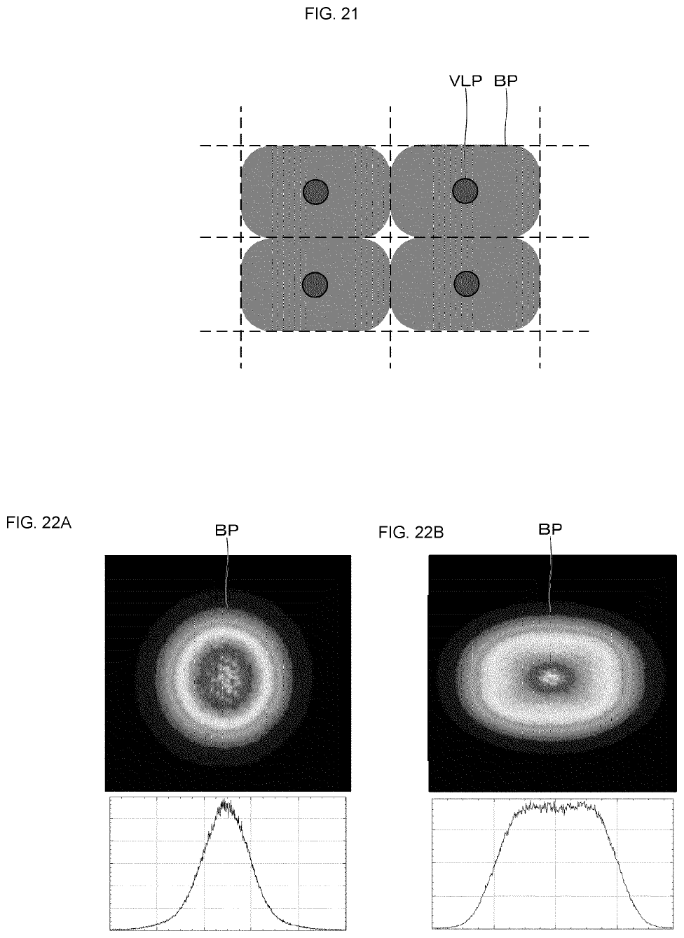

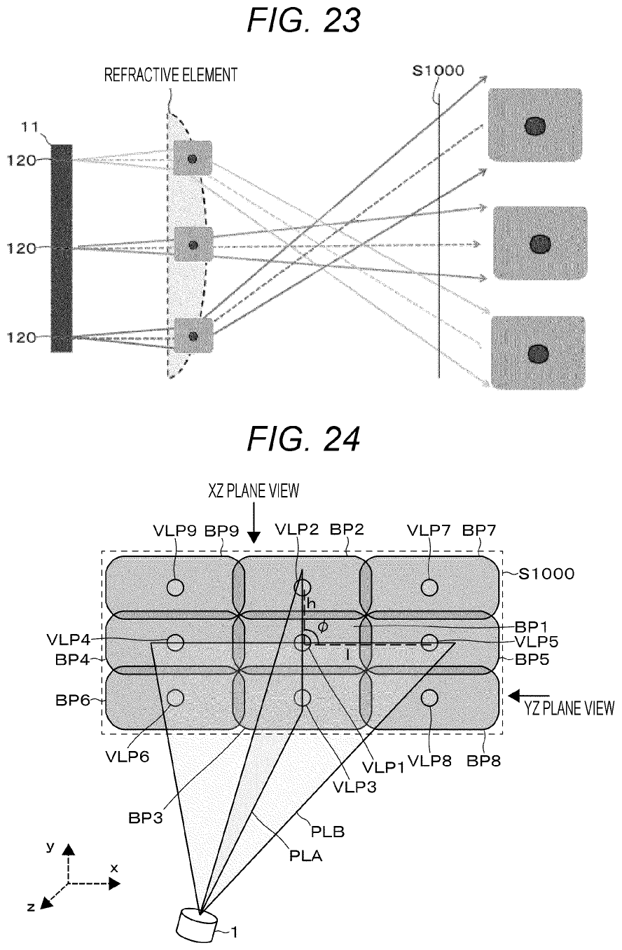

The cause of the non-uniformity of the laser intensity at the portion where the beam profiles BP overlap is considered to be that the shape of the beam profile BP is constant (specifically, circular) with respect to the arrangement of the light emission units (lattice shape, triangular shape, or the like). Therefore, in the present technology, the occurrence of the non-uniformity of the laser intensity described above is suppressed by matching the characteristics of the beam profile with respect to the arrangement of the light emission units, in other words, the arrangement of the light beam centers. For example, with respect to the arrangement of the light beam centers VLP as illustrated in FIG. 21, instead of the conventional circular beam profile BP as illustrated in FIG. 22A, a rectangular beam profile BP as illustrated in FIGS. 22B and 23 is used. Note that, in FIG. 23, the diffracted light is not illustrated. Hereinafter, a specific description will be given.

As illustrated in FIG. 24, with the illumination device 1 (as a more specific example, the position of the light emitting element 11) as a reference, a horizontal direction toward the paper surface in FIG. 24 is an X axis, a vertical direction (height direction) is a Y axis, and a depth direction is a Z axis. The screen S1000 is disposed on the light emission side of the illumination device 1. An array of light emitted from the light emitting element 11 (in this example, the light emission unit 120 for uniform irradiation) is illustrated on the screen S1000. Specifically, nine beam profiles BP are illustrated on the screen S1000. Of course, there are actually more beam profiles BP, but in this example, nine beam profiles BP are used in consideration of convenience of description.

Among the nine beam profiles BP, the central beam profile and the light beam center are defined as a beam profile BP1 and a light beam center VLP1. A beam profile on the upper side of the beam profile BP1 is a beam profile BP2 (light beam center VLP2), and a beam profile on the lower side of the beam profile BP1 is a beam profile BP3 (light beam center VLP3). In addition, a beam profile on the left side of the beam profile BP1 is a beam profile BP4 (light beam center VLP4), and a beam profile on the right side of the beam profile BP1 is a beam profile BP5 (light beam center VLP5). In addition, a lower left beam profile of the beam profile BP1 is a beam profile BP6 (light beam center VLP6), and an upper right beam profile of the beam profile BP1 is a beam profile BP7 (light beam center VLP7). In addition, a lower right beam profile of the beam profile BP1 is a beam profile BP8 (light beam center VLP8), and an upper left beam profile of the beam profile BP1 is a beam profile BP9 (light beam center VLP9).

Here, a plane PLA (YZ plane in this example) including the light beam center VLP1 (an example of a first light beam center), the light beam center VLP2 (an example of a second light beam center), and the light beam center VLP3 is defined. In addition, a plane PLB (XZ plane in this example) including the light beam center VLP1, the light beam center VLP4 (an example of a third light beam center), and the light beam center VLP5 is defined. An angle between the plane PLA and the plane PLB is defined as φ. In this example, φ=90 degrees. In addition, the light beam center VLP1 and the light beam center VLP2 are light beam centers adjacent to each other in the Y-axis direction.

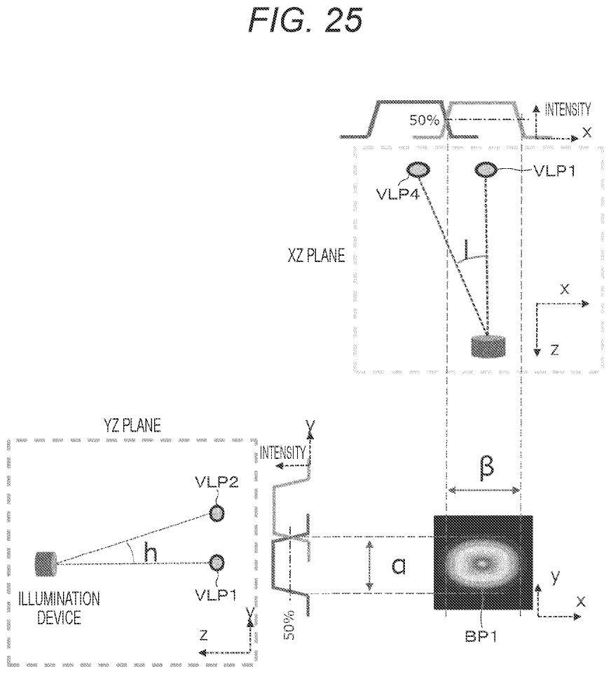

As illustrated in FIG. 25, in the plane PLA, an angle (first angle) formed by the light beam center VLP1 and the light beam center VLP2 with respect to the illumination device 1 (more specifically, the light emitting element 11 included in the illumination device 1) is an angle h. An angle (second angle) at which the beam intensity of the beam profile BP1 (XY beam profile) corresponding to the light beam center VLP1 is predetermined (50% in this example) in the extending direction (short direction in this example) of the line including the light beam center VLP1 and the light beam center VLP2 is defined as an angle α. In the present embodiment, the angle h and the angle α are substantially equal (angle h=angle α). Substantially equal means that for the angle h, a range from 75% to 25% of the predetermined intensity with respect to the center intensity that is the definition of the angle of the beam profile is allowed.

By making the angle h and the angle α substantially equal, the beam intensity at the portion where the beam profiles BP1 and BP2 overlap can be set to 100% (the sum of 50% and 50%). As a result, it is possible to suppress a decrease in beam intensity at a portion where beam profiles overlap. Note that, although the light beam center VLP1 and the light beam center VLP2 have been described as an example, similar things can be said for other two adjacent light beam centers.

In addition, as illustrated in FIG. 25, in the plane PLB, an angle (third angle) formed by the light beam center VLP1 and the light beam center VLP4 with respect to the illumination device 1 (more specifically, the light emitting element 11 included in the illumination device 1) is set as an angle l. An angle (fourth angle) at which the beam intensity of the beam profile BP1 corresponding to the light beam center VLP1 is predetermined (50% in this example) in the extending direction of the line including the light beam center VLP1 and the light beam center VLP4 is defined as an angle β. In the present embodiment, the angle l and the angle β are substantially equal (angle l=angle β). Substantially equal means that for the angle l, a range from 75% to 25% of the predetermined intensity with respect to the center intensity that is the definition of the angle of the beam profile is allowed.

By making the angle l and the angle β substantially equal, the beam intensity at the portion where the beam profiles BP1 and BP4 overlap can be set to 100% (the sum of 50% and 50%). As a result, it is possible to suppress a decrease in beam intensity at a portion where beam profiles overlap. Note that, although the light beam center VLP1 and the light beam center VLP4 have been described as an example, similar things can be said for other two adjacent light beam centers.

By setting the beam profile BP that satisfies the relationship described above, it is possible to suppress a decrease in beam intensity at a portion where the beam profiles BP overlap in uniform irradiation.

Note that, in the example illustrated in FIG. 25, the example in which the shape of the beam profile is rectangular has been described, but the present invention is not limited thereto. For example, as illustrated in FIG. 26A, the shape of the beam profile may be a square shape. In this case, the angle h and the angle l illustrated in FIG. 26B are substantially equal. In addition, the angle φ is 90 degrees.

As illustrated in FIG. 27, the shape of the beam profile BP may be an equilateral triangle. In FIG. 27, an angle formed by the light beam center VLP1 and the light beam center VLP2 with respect to the light emitting element 11 is h1, an angle formed by the light beam center VLP1 and the light beam center VLP3 with respect to the light emitting element 11 is l1, and an angle formed by a plane including the light beam center VLP1 and the light beam center VLP2 and a plane including the light beam center VLP1 and the light beam center VLP3 is an angle φ1. In addition, an angle formed by the light beam center VLP1 and the light beam center VLP4 with respect to the light emitting element 11 is h2, an angle formed by the light beam center VLP4 and the light beam center VLP5 with respect to the light emitting element 11 is l2, and an angle formed by a plane including the light beam center VLP1 and the light beam center VLP4 and a plane including the light beam center VLP4 and the light beam center VLP5 is an angle φ2. In the case of this example, an array of light beam centers having the following arrays (1) and (2) as the minimum period is obtained.
(1) l1: array having a substantially parallelogram shape with h1=√3 and φ1=30 degrees
(2) l2: array having a substantially rectangular shape with h2=√3 and φ2=90 degrees

Where l1=l2 is satisfied.

The shape of the beam profile BP may be a substantially hexagonal shape illustrated in FIGS. 28A and 28B. FIG. 28A illustrates one beam profile, and FIG. 28B is a diagram schematically illustrating a plurality of beam profiles with which an irradiation target object 1000 or the like is irradiated. In FIG. 28B, an angle formed by the light beam center VLP1 and the light beam center VLP2 is defined as an angle h. In addition, an angle formed by the light beam center VLP1 and the light beam center VLP3 is defined as an angle l. An angle formed by a plane including the light beam center VLP1 and the light beam center VLP2 and a plane including the light beam center VLP1 and the light beam center VLP3 is defined as an angle φ. In this case, angle l=angle h is established, and φ=60 degrees.

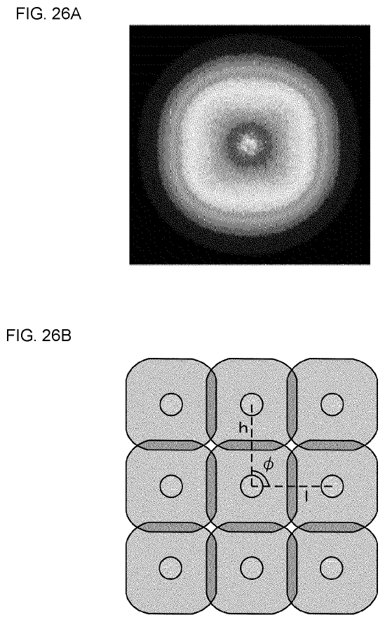

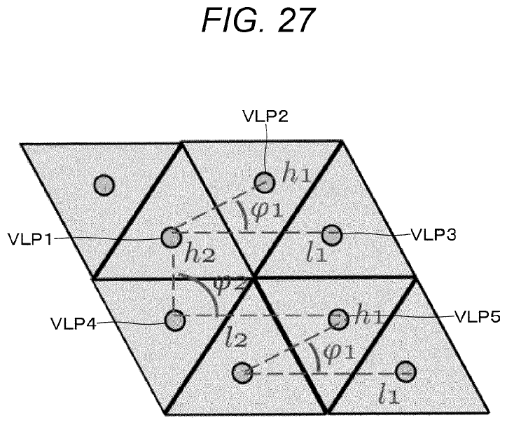

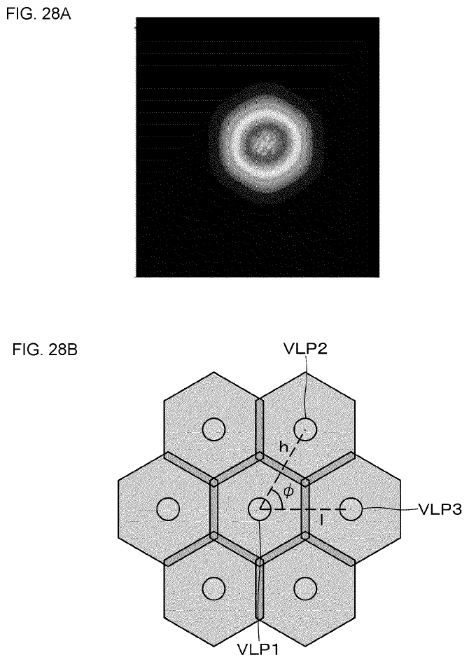

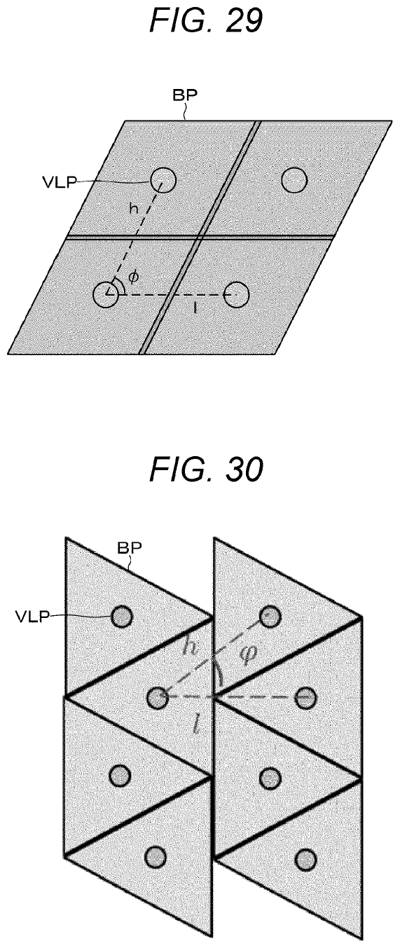

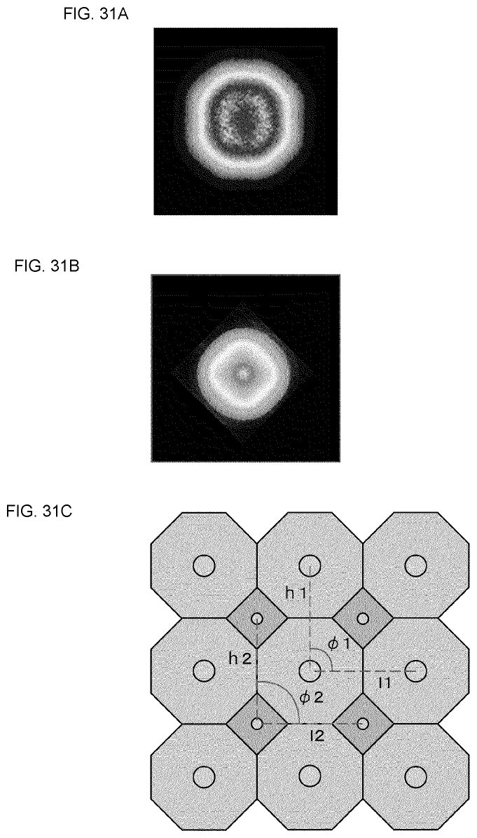

In addition, the shape of the beam profile BP may be a parallelogram as illustrated in FIG. 29. In addition, as illustrated in FIG. 30, the beam profile BP may have an equilateral triangular shape and may be arranged differently from that in FIG. 27. In addition, the beam profile BP may have a shape in which a regular octagonal beam profile BP and a square beam profile BP as illustrated in FIG. 31A are combined (see FIG. 31C).

### Shaping Example of Beam Profile

An example of a method of shaping a beam profile of a laser beam having a substantially circular beam profile into a beam profile satisfying the above-described relationship will be described.

The first example is an example in which the beam profile corresponds to the shape of the light emission port 151A of the light emission unit 120. FIG. 32A is a partial cross-sectional view of the light emitting element 11, specifically, the light emission unit 120. FIG. 32B is a top view of the configuration illustrated in FIG. 32A. Note that, in FIGS. 32A and 32B, illustration of some configurations is simplified.

As illustrated in FIG. 32A, an annular upper electrode 151 having a light emission port 151A is formed in a region of the active layer 143 facing the light emitting region 143A. When the shape of the light emission port 151A is, for example, a square shape like the light emission port 151A in FIG. 32A, a beam profile BP in which the XY beam profile is a square shape as illustrated in FIG. 32C can be obtained.

The second example is an example in which the beam profile corresponds to the shape of the light emitting region of the light emission unit 120. As illustrated in FIGS. 33A and 33B, the light emitting region means a light emission area (the above-described OA diameter W4) of the light emission unit 120. By setting the shape of the light emitting region to, for example, a square shape, it is possible to obtain a beam profile BP in which the XY beam profile is a square shape as illustrated in FIG. 33C, for example.

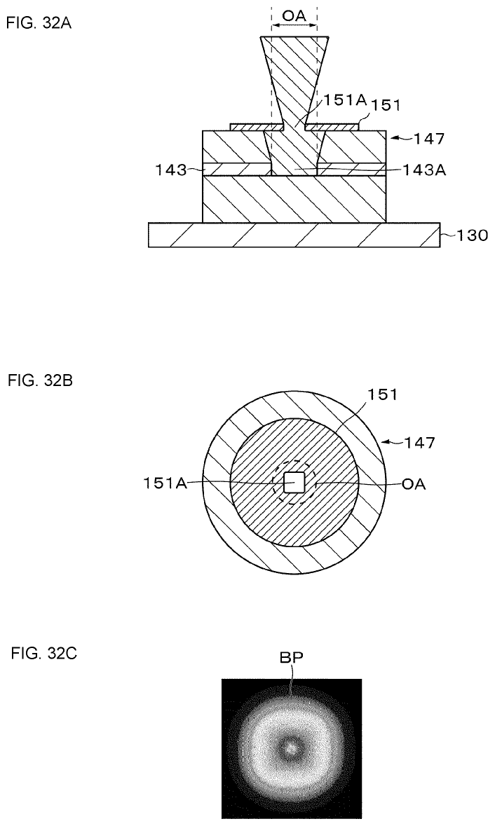

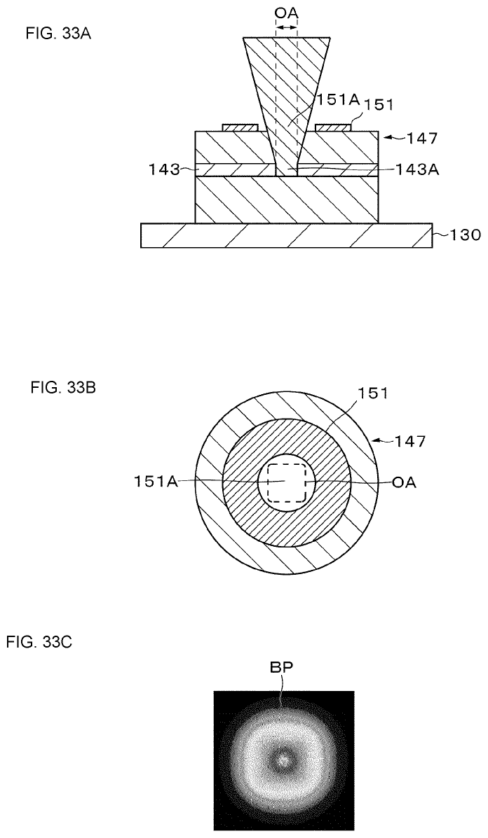

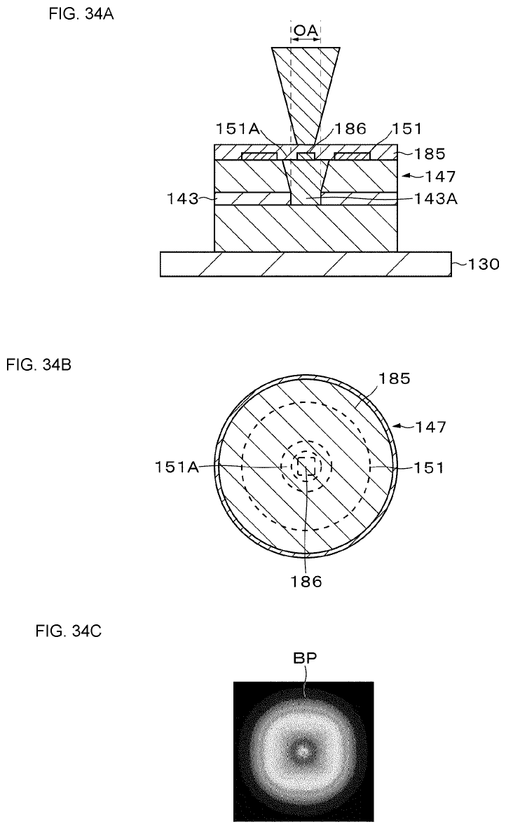

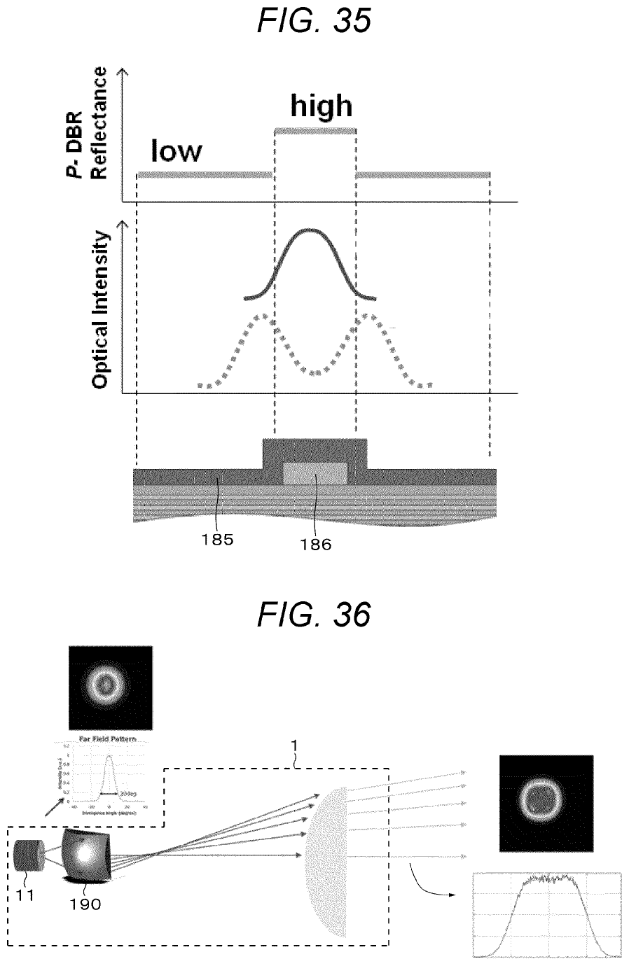

The third example is an example in which the beam profile BP is formed by providing a structure (SR structure) in which the reflectance is controlled depending on the location and the output of the outer periphery is suppressed, that is, a layer structure having different reflectances, for each thickness of the refractive material for each surface multilayer in the opening 151A of the upper electrode 151. For example, as illustrated in FIG. 35, the SR structure is an example in which a second layer 186 is provided in a part of a first layer 185 so that the reflectance of the portion of the second layer 186 is higher than that of the surroundings. As illustrated in FIG. 34A, the second layer 186 is formed at a position facing the light emitting region 143A by vapor deposition or the like. As a result, the output of light to the periphery of the second layer 186 is suppressed, and for example, a beam profile BP in which the XY beam profile has a square shape as illustrated in FIG. 34C can be obtained.

The fourth example is an example in which the beam profile BP is formed by a predetermined optical member. For example, as illustrated in FIG. 36, the optical member 190 is disposed at a position of 10 to 100 μm with respect to the light emitting element 11. As the optical member 190, for example, a microlens that is convex in a direction in which light is incident can be used. By using the optical member 190, for example, as illustrated in FIG. 36, a single peak beam profile having a circular XY beam profile and a narrow Z beam profile can be formed into a beam profile having a square XY beam profile and a top-hat Z beam profile.

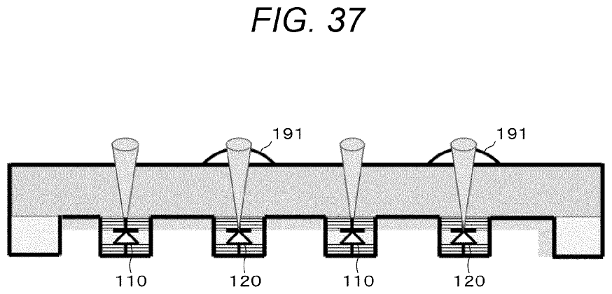

The fifth example is an example in which an on-chip lens 191 is provided on the light emission side of the light emission unit 120 as illustrated in FIG. 37. It is also possible to create a predetermined beam profile by the on-chip lens 191.

### Example of Setting Predetermined Intensity

In the above description, it has been described that the angle formed by two adjacent light beam centers is substantially equal to the angle when the angle of the beam profile becomes the predetermined intensity with respect to the peak intensity, and 50% is taken as an example of the predetermined intensity, but the present invention is not limited thereto. For example, the predetermined intensity may be different depending on the adjacent direction of two adjacent light beam centers.

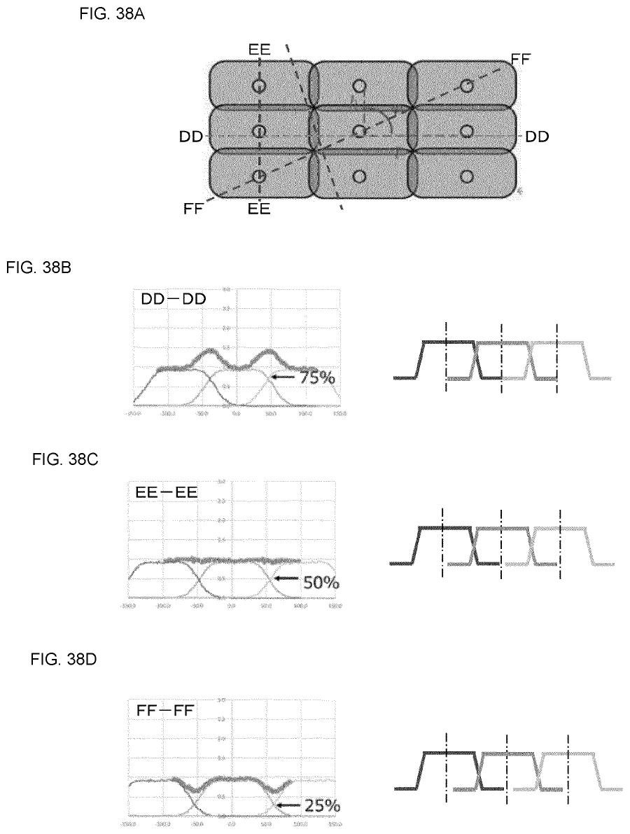

For example, as illustrated in FIG. 38A, the angle formed by the two light beam centers in the DD-DD direction (horizontal direction) is made substantially equal to the angle when the angle of the beam profile becomes 75% with respect to the peak intensity. In this case, as illustrated in FIG. 38B, the beam intensity (upper limit of the beam intensity) at the portion where the two beam profiles overlap in the DD-DD direction is +50%. Furthermore, as illustrated in FIG. 38A, the angle formed by the two light beam centers in the EE-EE direction (vertical direction) is made substantially equal to the angle when the angle of the beam profile becomes 50% with respect to the peak intensity. In this case, as illustrated in FIG. 38C, the beam intensity (upper limit of the beam intensity) at the portion where the two beam profiles overlap in the EE-EE direction is 1 (+0%). As illustrated in FIG. 38A, the angle formed by the two light beam centers in the FF-FF direction (diagonal direction) is made substantially equal to the angle when the angle of the beam profile becomes 25% with respect to the peak intensity. In this case, as illustrated in FIG. 38D, the beam intensity (upper limit of the beam intensity) at the portion where the two beam profiles overlap in the FF-FF direction is −50%. Practically, the beam intensity is considered to be acceptable up to −50%, so that the predetermined intensity is preferably set in a range up to 25 to 75%.

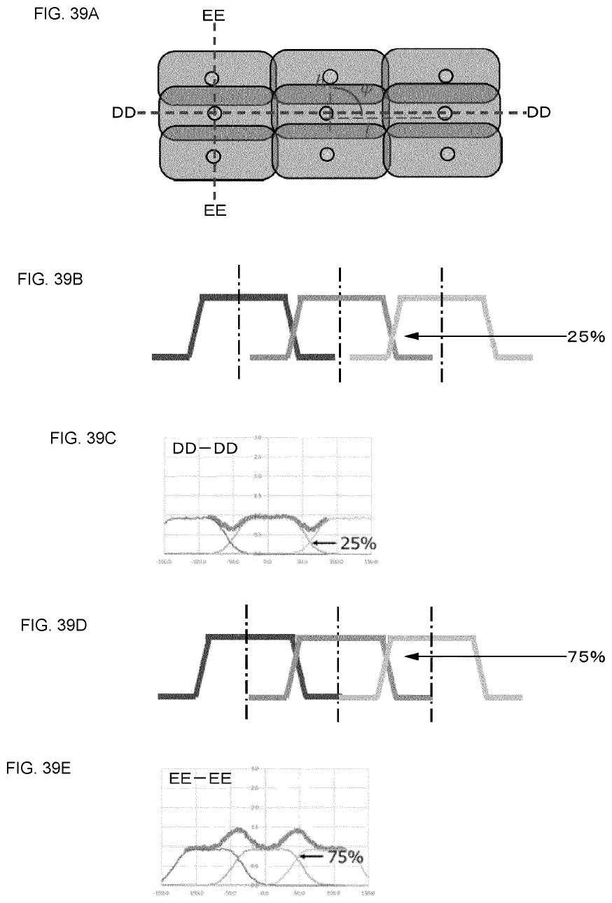

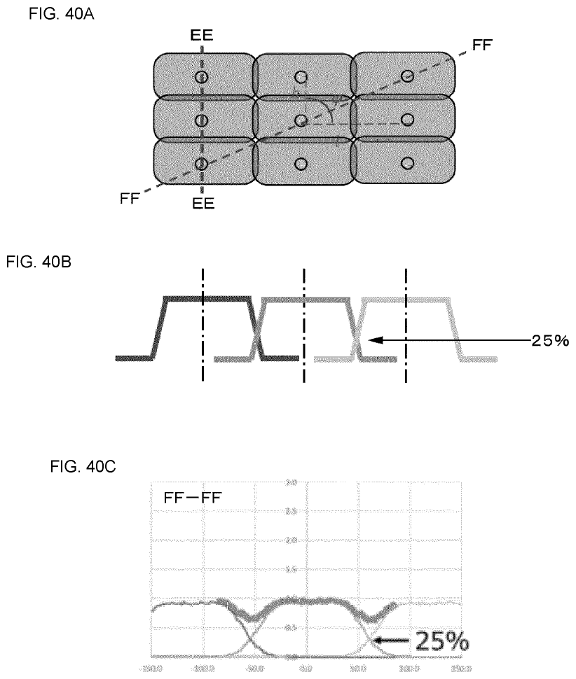

In addition, as illustrated in FIG. 39A, the angle formed by the two light beam centers in the DD-DD direction (horizontal direction) may be substantially equal to the angle when the angle of the beam profile becomes 25% with respect to the peak intensity as illustrated in FIG. 39B. In this case, as illustrated in FIG. 39C, the decrease in the beam intensity of the portion where the two beam profiles overlap in the DD-DD direction can be set to up to −50%. As illustrated in FIG. 39A, the angle formed by the two light beam centers in the EE-EE direction (vertical direction) is made substantially equal to the angle when the angle of the beam profile becomes 75% with respect to the peak intensity as illustrated in FIG. 39D. In this case, as illustrated in FIG. 39E, the beam intensity of the portion where the two beam profiles overlap in the EE-EE direction can be set to +50%. As described above, when the beam profile has a rectangular shape, the overlapping in the short direction may be increased, and the overlapping in the longitudinal direction may be decreased. Furthermore, in the example illustrated in FIG. 39, the angle formed by the two light beam centers in the FF-FF direction (diagonal direction) illustrated in FIG. 40A may be substantially equal to the angle when the angle of the beam profile becomes 25% with respect to the peak intensity as illustrated in FIG. 40B. In this case, as illustrated in FIG. 40C, the decrease in the beam intensity of the portion where the two beam profiles overlap in the FF-FF direction can be set to up to −50%. Even in the example described with reference to FIGS. 38 to 40, it is possible to obtain similar effects to the above-described effects.

### Modifications

Although the embodiment of the present disclosure has been specifically described above, the content of the present disclosure is not limited to the above-described embodiment, and various modifications based on the technical idea of the present disclosure are possible. Hereinafter, each of a plurality of modifications will be described. Note that configurations identical or similar to those of the embodiment are denoted by the same reference numerals, and redundant description will be omitted as appropriate.

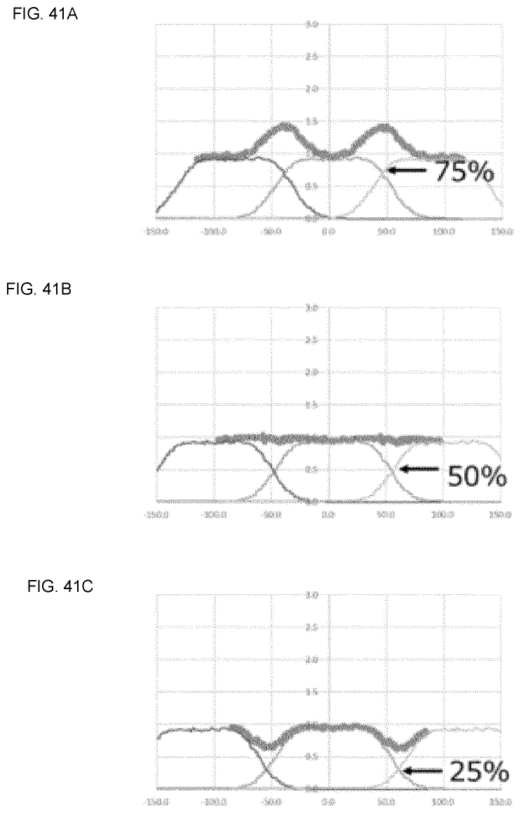

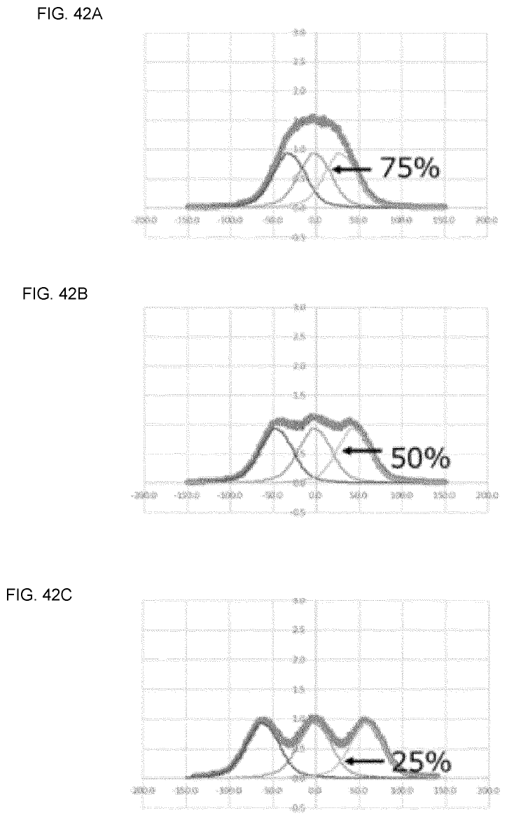

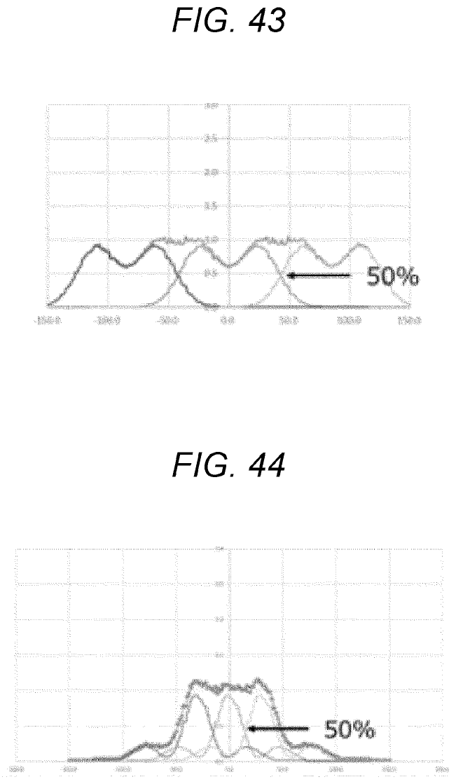

In the above-described embodiment, the so-called top-hat beam profile illustrated in FIGS. 41A to 41C has been described as an example, but the present invention is not limited thereto. For example, as illustrated in FIGS. 42A to 42C, the shape of each beam profile may be a Gaussian shape. In addition, as illustrated in FIG. 43, the shape of each beam profile may be a bimodal shape (a shape having two peaks). In addition, as illustrated in FIG. 44, the shape of each beam profile may be a trimodal shape (a shape having one peak and two peaks smaller than the peak).

Note that the above embodiment illustrates an example for embodying the present technology, and matters in the embodiment and matters specifying the invention in the claims have correspondence relationships. Similarly, the matters specifying the invention in the claims and matters having the same names in the embodiment of the present technology have correspondence relationships. However, the present technology is not limited to the embodiment and can be embodied by making various modifications to the embodiment without departing from the gist thereof.

Note that effects described in the present specification are merely examples and are not limited, and there may also be other effects.

Note that the present technology can also take the following configurations.
(1)

An illumination device including
a light emitting element including a plurality of light emission units,
in which, when an irradiation target object is irradiated with a light beam emitted from the plurality of light emission units, in a case where a portion corresponding to a center of the light beam is set as a light beam center, and predetermined two light beam centers are set as a first light beam center and a second light beam center, and
in a case where an angle formed by the first light beam center and the second light beam center with respect to the light emitting element is set as a first angle, and an angle at which a beam intensity of a beam profile corresponding to the first light beam center becomes a predetermined intensity in an extending direction of a line including the first light beam center and the second light beam center is set as a second angle, the first angle is substantially equal to the second angle.
(2)

The illumination device according to (1),
in which the first light beam center and the second light beam center are light beam centers adjacent to each other in a predetermined direction.
(3)

The illumination device according to (2),
in which, in a case where a light beam center adjacent to the first light beam center in a direction different from the predetermined direction is set as a third light beam center, an angle formed by the first light beam center and the third light beam center is set as a third angle, and an angle at which a beam intensity of a beam file corresponding to the first light beam center becomes a predetermined intensity in an extending direction of a line including the first light beam center and the third light beam center is set as a fourth angle, the third angle is substantially equal to the fourth angle.
(4)

The illumination device according to (3),
in which an angle o formed by a plane including the first light beam center and the second light beam center and a plane including the first light beam center and the third light beam center is 30 degrees or 90 degrees.
(5)

The illumination device according to (4),
in which the first angle and the third angle are substantially equal to each other.
(6)

The illumination device according to any one of (1) to (5),
in which the predetermined intensity is set between 25% and 75% with respect to a peak of a beam intensity.
(7)

The illumination device according to (6),
in which the predetermined intensity is 50%.
(8)

The illumination device according to any one of (1) to (7),
in which the beam profile is a beam profile corresponding to a shape of a light emission port of the light emitting element.
(9)

The illumination device according to any one of (1) to (7),
in which the beam profile is a beam profile corresponding to a shape of a light emitting region of the light emitting element.
(10)

The illumination device according to any one of (1) to (7),
in which the beam profile is formed by providing a layer structure having different reflectance on a light beam emission side of a light emitting region of the light emission unit.
(11)

The illumination device according to (1,
in which the beam profile is formed by a predetermined optical member.
(12)

The illumination device according to (1),
the light emitting element including a plurality of first light emission units and a plurality of second light emission units,
the illumination device further including:
a first optical member that emits a plurality of first light emitted from the plurality of first light emission units and a plurality of second light emitted from the plurality of second light emission units in substantially parallel to each other;
a second optical member that shapes a beam shape of at least one of the plurality of first light or the plurality of second light, and emits the plurality of first light and the plurality of second light as light having beam shapes different from each other; and
a third optical member that is disposed on an optical path of the plurality of first light and the plurality of second light, refracts or diffracts the plurality of first light to increase the number of spots applied on the irradiation target object, and refracts or diffracts the plurality of second light to increase an overlapping range with the second light emitted from the second light emission unit adjacent,
in which the plurality of first light emitted from the plurality of first light emission units is applied to the irradiation target object in a spot irradiation pattern,
the plurality of second light emitted from the plurality of second light emission units is overlapped on the irradiation target object with the second light emitted from the second light emission unit partially adjacent, and a predetermined range is irradiated with the second light in a uniform irradiation pattern, and
when the irradiation target object is irradiated with a light beam emitted from the plurality of first light emission units, in a case where a position corresponding to a center of the light beam is set as a light beam center, and predetermined two light beam centers are set as a first light beam center and a second light beam center, and
in a case where an angle formed by the first light beam center and the second light beam center with respect to the light emitting element is set as a first angle, and an angle at which a beam intensity of a beam profile corresponding to the first light beam center becomes a predetermined intensity in an extending direction of a line including the first light beam center and the second light beam center is set as a second angle, the first angle is substantially equal to the second angle.
(13)

A distance measuring device including:
the illumination device according to any one of (1) to (12);
a control unit that controls the illumination device;
a light receiving unit that receives reflected light reflected from a target object; and
a distance measuring unit that calculates a distance measurement distance from image data obtained by the light receiving unit.

### REFERENCE SIGNS LIST

1 Illumination device
11 Light emitting element
23 Cathode electrode
24, 25 Anode electrode
100 Distance measuring device
110 Light emission unit
120 Light emission unit
130 n-type substrate
143 Active layer
151A Light emission port
h, l, α, β Angle

1. An illumination device comprising
a light emitting element including a plurality of light emission units,
wherein, when an irradiation target object is irradiated with a light beam emitted from the plurality of light emission units, in a case where a portion corresponding to a center of the light beam is set as a light beam center, and predetermined two light beam centers are set as a first light beam center and a second light beam center, and
in a case where an angle formed by the first light beam center and the second light beam center with respect to the light emitting element is set as a first angle, and an angle at which a beam intensity of a beam profile corresponding to the first light beam center becomes a predetermined intensity in an extending direction of a line including the first light beam center and the second light beam center is set as a second angle, the first angle is substantially equal to the second angle.

2. The illumination device according to claim 1,
wherein the first light beam center and the second light beam center are light beam centers adjacent to each other in a predetermined direction.

3. The illumination device according to claim 2,
wherein, in a case where a light beam center adjacent to the first light beam center in a direction different from the predetermined direction is set as a third light beam center, an angle formed by the first light beam center and the third light beam center is set as a third angle, and an angle at which a beam intensity of a beam file corresponding to the first light beam center becomes a predetermined intensity in an extending direction of a line including the first light beam center and the third light beam center is set as a fourth angle, the third angle is substantially equal to the fourth angle.

4. The illumination device according to claim 3,
wherein an angle φ formed by a plane including the first light beam center and the second light beam center and a plane including the first light beam center and the third light beam center is 30 degrees or 90 degrees.

5. The illumination device according to claim 4,
wherein the first angle and the third angle are substantially equal to each other.

6. The illumination device according to claim 1,
wherein the predetermined intensity is set between 25% and 75% with respect to a peak of a beam intensity.

7. The illumination device according to claim 6,
wherein the predetermined intensity is 50%.

8. The illumination device according to claim 1,
wherein the beam profile is a beam profile corresponding to a shape of a light emission port of the light emitting element.

9. The illumination device according to claim 1,
wherein the beam profile is a beam profile corresponding to a shape of a light emitting region of the light emitting element.

10. The illumination device according to claim 1,
wherein the beam profile is formed by providing a layer structure having different reflectance on a light beam emission side of a light emitting region of the light emission unit.

11. The illumination device according to claim 1,
wherein the beam profile is formed by a predetermined optical member.

12. The illumination device according to claim 1,
the light emitting element including a plurality of first light emission units and a plurality of second light emission units,
the illumination device further comprising:
a first optical member that emits a plurality of first light emitted from the plurality of first light emission units and a plurality of second light emitted from the plurality of second light emission units in substantially parallel to each other;
a second optical member that shapes a beam shape of at least one of the plurality of first light or the plurality of second light, and emits the plurality of first light and the plurality of second light as light having beam shapes different from each other; and
a third optical member that is disposed on an optical path of the plurality of first light and the plurality of second light, refracts or diffracts the plurality of first light to increase the number of spots applied on the irradiation target object, and refracts or diffracts the plurality of second light to increase an overlapping range with the second light emitted from the second light emission unit adjacent,
wherein the plurality of first light emitted from the plurality of first light emission units is applied to the irradiation target object in a spot irradiation pattern,
the plurality of second light emitted from the plurality of second light emission units is overlapped on the irradiation target object with the second light emitted from the second light emission unit partially adjacent, and a predetermined range is irradiated with the second light in a uniform irradiation pattern, and
when the irradiation target object is irradiated with a light beam emitted from the plurality of first light emission units, in a case where a position corresponding to a center of the light beam is set as a light beam center, and predetermined two light beam centers are set as a first light beam center and a second light beam center, and
in a case where an angle formed by the first light beam center and the second light beam center with respect to the light emitting element is set as a first angle, and an angle at which a beam intensity of a beam profile corresponding to the first light beam center becomes a predetermined intensity in an extending direction of a line including the first light beam center and the second light beam center is set as a second angle, the first angle is substantially equal to the second angle.

13. A distance measuring device comprising:
the illumination device according to claim 1;
a control unit that controls the illumination device;
a light receiving unit that receives reflected light reflected from a target object; and
a distance measuring unit that calculates a distance measurement distance from image data obtained by the light receiving unit.
